(19) United States
(12) Patent Application Publication
(10) Pub. No.: US 2013/0175519 A1
(43) Pub. Date: Jul. 11, 2013

(54) NEW CONDENSED POLYCYCLIC COMPOUND AND ORGANIC LIGHT-EMITTING ELEMENT USING THE SAME

(71) Applicants: Naoki Yamada, Inagi-shi (JP); Jun Kamatani, Tokyo (JP); Kengo Kishino, Tokyo (JP); Hiroyuki Tomono, Numazu-shi (JP); Tomona Yamaguchi, Tokyo (JP)

(72) Inventors: Naoki Yamada, Inagi-shi (JP); Jun Kamatani, Tokyo (JP); Kengo Kishino, Tokyo (JP); Hiroyuki Tomono, Numazu-shi (JP); Tomona Yamaguchi, Tokyo (JP)

(73) Assignee: CANON KABUSHIKI KAISHA, Tokyo (JP)

(21) Appl. No.: 13/822,443

(22) PCT Filed: Aug. 23, 2011
(86) PCT No.: PCT/JP2011/069367

§ 371 Date: Mar. 12, 2013

(30) Foreign Application Priority Data
Sep. 13, 2010 (JP) 2010-204248
May 19, 2011 (JP) 2011-112777

(51) Int. Cl. H01L 51/00

(52) U.S. Cl. CPC H01L 51/0035
USPC 257/40; 549/43; 548/445; 546/255; 546/256; 585/27

(57) ABSTRACT

The present invention provides a stable new condensed polycyclic compound which is not likely to form a molecular association. In addition, the present invention also provides an organic light-emitting element having a high light-emitting efficiency and a low drive voltage. In the condensed polycyclic compound in Claim 1 represented by the general formula [1], R1, R2 and R5 are each independently selected from a hydrogen atom, an alkyl group having 1 to 4 carbon atoms, an aryl group, and a heterocyclic group. R3 and R4 each represent an alkyl group having 1 to 4 carbon atoms. The aryl group and the heterocyclic group each may have at least one of an alkyl group, an aralkyl group, an aryl group, a heterocyclic group, an amino group, and an alkoxy group as a substituent.

### TECHNICAL FIELD

The present invention relates to a new condensed polycyclic compound and an organic light-emitting element using the same.

### BACKGROUND ART

An organic light-emitting element is an element having a pair of electrodes and an organic compound layer provided therebetween. By injecting electrons and holes from the pair of electrodes, excitons of a light-emitting organic compound in the organic compound layer are generated, and when the excitons return to the ground state, light is emitted.

In Patent Literature 1, triphenylene (H-2) shown below has been disclosed. In addition, a compound including triphenylene as a mother skeleton has also been disclosed as a host material of a light-emitting layer of a phosphorescent light-emitting element.

In addition, in Patent Literature 2, as one structural example liable to form a molecular association, 4H-cyclopenta[def]triphenylene (H-3) has been disclosed. The structure thereof is shown below.

In this structure, the mother skeleton is a condensed ring having a conjugated structure.

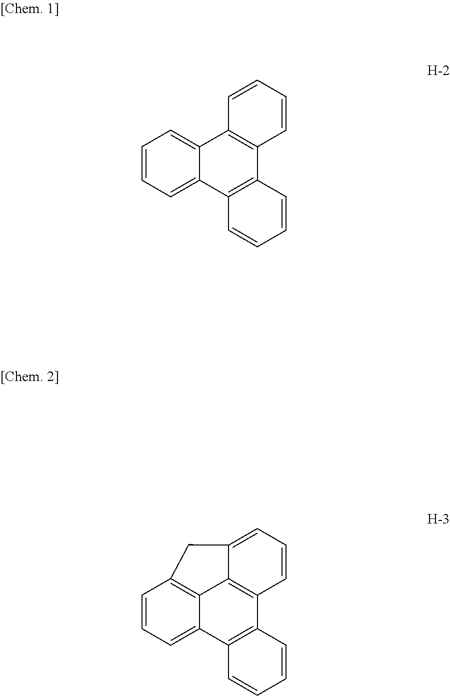

### CITATION LIST

### Patent Literatures

PTL 1 International Publication No. WO2006/130598 pamphlet
PTL 2 U.S. Patent Application Publication No. 2004/0076853

### SUMMARY OF INVENTION

The triphenylene disclosed in Patent Literature 1 is a compound having a high T1 and excellent thermal stability. However, since this triphenylene has a high molecular planarity, an association is disadvantageously liable to occur between molecules, and compounds having 4H-cyclopenta[def]triphenylene and triphenylene as a mother skeleton also have disadvantage similar to that described above. The association formed between molecules is not preferable since the properties of the compound are changed.

Hence, the present invention provides a stable new condensed polycyclic compound which is not likely to form a molecular association. In addition, the present invention also provides an organic light-emitting element using the above compound, which has a high light-emitting efficiency and a low drive voltage.

Accordingly, the present invention provides a condensed polycyclic compound represented by the following general formula [1].

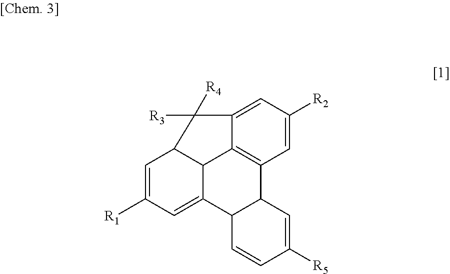

In the general formula [1], R1, R2, and R5 are each independently selected from a hydrogen atom, an alkyl group having 1 to 4 carbon atoms, an aryl group, and a heterocyclic group. R3 and R4 each represent an alkyl group having 1 to 4 carbon atoms.

The aryl group and the heterocyclic group may have at least one selected from an alkyl group, an aralkyl group, an aryl group, a heterocyclic group, an amino group, and an alkoxy group as a substituent.

According to the present invention, a stable new condensed polycyclic compound which is not likely to form a molecular association can be provided. In addition, since the new condensed polycyclic compound of the present invention is used for an organic light-emitting element, an organic light-emitting element having a high light-emitting efficiency and a low drive voltage can be provided.

### BRIEF DESCRIPTION OF DRAWINGS

FIG. 1 is a schematic cross-sectional view showing an organic light-emitting element and a switching element connected thereto.

### DESCRIPTION OF EMBODIMENTS

The present invention relates to a condensed polycyclic compound represented by the following general formula [1].

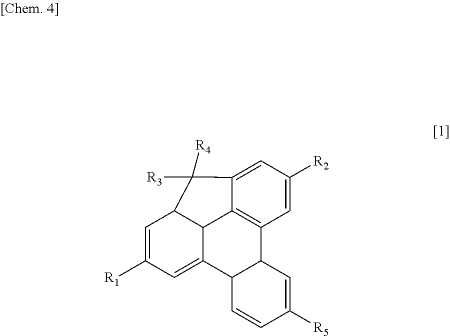

In the general formula [1], R1, R2, and R5 are each independently selected from a hydrogen atom, an alkyl group having 1 to 4 carbon atoms, an aryl group, and a heterocyclic group. R3 and R4 each represent an alkyl group having 1 to 4 carbon atoms.

The aryl group and the heterocyclic group may have at least one selected from an alkyl group, an aralkyl group, an aryl group, a heterocyclic group, an amino group, and an alkoxy group as a substituent. As a particular example of the alkyl group having 1 to 4 carbon atoms used as at least one of R1, R2, and R5 of the general formula [1], for example, a methyl group, an ethyl group, an n-propyl group, an iso-propyl group, an n-butyl group, an iso-butyl group, a sec-butyl group, and a tert-butyl group may be mentioned. As a particular example of the alkyl group having 1 to 4 carbon atoms used as at least one of R3 and R5 of the general formula [1], for example, a methyl group, an ethyl group, an n-propyl group, an iso-propyl group, an n-butyl group, an iso-butyl group, a sec-butyl group, and a tert-butyl group may be mentioned. As a particular example of the aryl group used as at least one of R1, R2, and R5 of the general formula [1], for example, there may be mentioned a phenyl group, a naphthyl group, a pentalenyl group, an indenyl group, an azulenyl group, an anthryl group, a pyrenyl group, an indacenyl group, an acenaphthenyl group, a phenanthryl group, a phenarenyl group, a fluoranthenyl group, an acephenanthryl group, an aceanthryl group, a triphenylenyl group, a chrysenyl group, a naphthacenyl group, a perylenyl group, a pantacenyl group, a biphenyl group, a terphenyl group, and a fluorenyl group. Among those mentioned above, a biphenyl group, a terphenyl group, and a fluorenyl group are particularly preferable. As a particular example of the heterocyclic group used as at least one of R1, R2, and R5 of the general formula [1], for example, there may be mentioned a thienyl group, a benzothiophenyl group, a dibenzothiophenyl group, a pyrrolyl group, a pyridyl group, an oxazolyl group, an oxadiazolyl group, a thiazolyl group, a thiadiazolyl group, a terthienyl group, a carbazolyl group, an acridinyl group, and a phenanthrolyl group. Among those mentioned above, a dibenzothiophenyl group and a pyridyl group are particularly preferable.

As the substituent which the aryl group and the heterocyclic group may have, for example, there may be mentioned alkyl groups, such as a methyl group, an ethyl group, and a propyl group; aralkyl groups, such as a benzyl group and a phenethyl group; aryl groups, such as a phenyl group and a biphenyl group; heterocyclic groups, such as a thienyl group, a pyrrolyl group, and a pyridyl group; amino groups, such as a dimethylamino group, a diethylamino group, a dibenzylamino group, a diphenylamino group, a ditolylamino group, and a dianisolylamino group; and alkoxyl groups, such as a methoxyl group, an ethoxyl group, a propoxyl group, and a phenoxyl group.

Since the condensed polycyclic compound of the present invention has alkyl groups as R3 and R4 of the general formula [1], a molecular association can be suppressed from being formed. In addition, since the condensed polycyclic compound of the present invention forms no molecular association, absorption and emission of light by the molecular association state are not observed.

Furthermore, as the condensed polycyclic compound of the present invention, a compound is preferable in which R5 of the general formula [1] represents a phenyl group, a biphenyl group, or a fluorenyl group.

The reason for this is that the compound in which one of the above groups is provided as R5 further suppresses the formation of a molecular association and also increases the glass transition temperature.

A compound containing a phenyl group as R5 is represented by general formula [2], a compound containing a biphenyl group as R5 is represented by general formula [3], and a compound containing a fluorenyl group as R5 is represented by general formula [4].

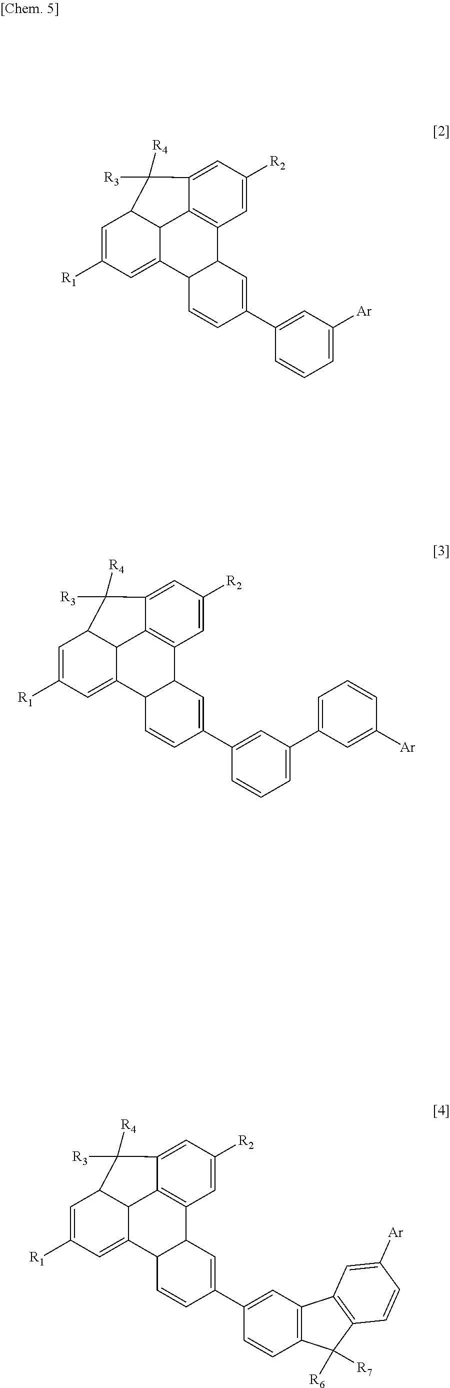

Ar of each of the general formulas [2] to [4] is one selected from a hydrogen atom, an alkyl group having 1 to 4 carbon atoms, a substituted or non-substituted aryl group, and a substituted or non-substituted heterocyclic group. A particular example of each substituent is the same as that of the example of the substituent of the general formula [1]. The general formula [3] is particularly preferable among the general formulas [2] to [4]. The reason for this is that the condensed polycyclic compound represented by the general formula [3] has a significantly high effect of suppressing the formation of a molecular association.

As one example of the compound of the present invention, the following compound A-2-8 is mentioned. As a comparative compound therewith, the following compound e-1 is mentioned. Hereinafter, by comparing the compound A-2-8 with the compound e-1, the condensed polycyclic compound of the present invention will be described.

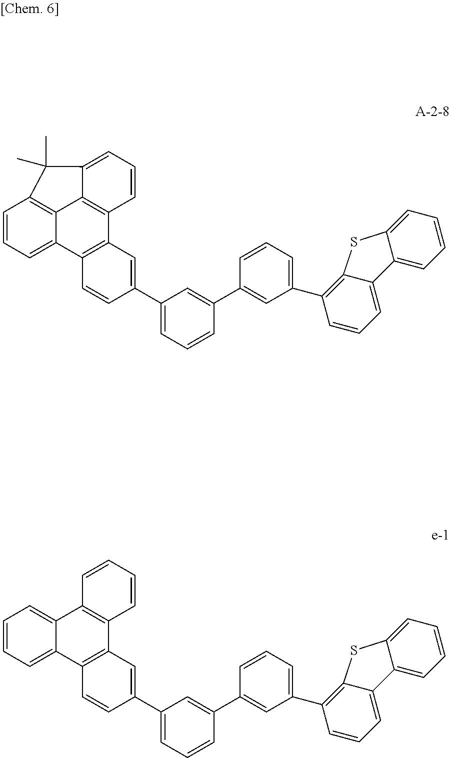 [SMILES: CC1(C)c2cccc3c4ccc(-c5cccc(-c6cccc(-c7cccc8c7sc7ccccc78)c6)c5)cc4c4cccc1c4c23 ; c1cc(-c2cccc(-c3cccc4c3sc3ccccc34)c2)cc(-c2ccc3c4ccccc4c4ccccc4c3c2)c1]

The following H-1 is mentioned as a part of the structure of the condensed polycyclic compound of the present invention. Hereinafter, H-1 will be compared with triphenylene (H-2).

H-1 is different from triphenylene (H-2) in terms of the following four properties.

1. Fluorescence quantum yield is high.
2. Sublimability is high.
3. Ionization potential (IP) is low.
4. Molecular association is not likely to occur.

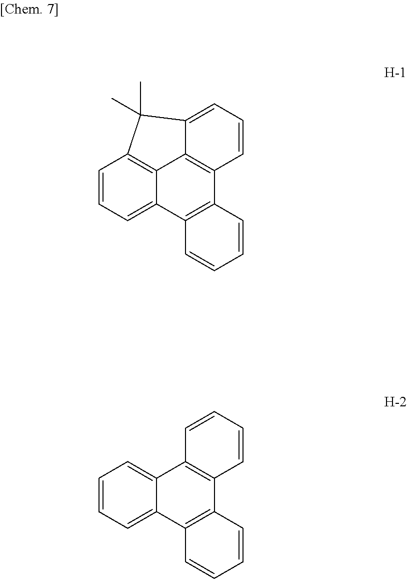

### 1. Comparison of Fluorescence Quantum Yield

Since triphenylene (H-2) has the C3 symmetry, the transition properties of light emission are symmetry forbidden. That is, since the symmetry is high, light is hardly emitted. On the other hand, since the partial structure (H-1) of the new condensed polycyclic compound of the present invention has low symmetry, the symmetry forbidden level is lowered, and the fluorescence quantum yield is high as compared with that of triphenylene. The measured values of the fluorescence quantum yields are shown in Table 1.

TABLE 1

| COMPOUND NAME | FLUORESCENCE QUANTUM YIELD |
|---|---|
| H-1 | 0.29 |
| H-2 | 0.085 |

Measurement of the fluorescence quantum yield was performed in a cyclohexane solution at a concentration of 1×10⁻⁶ mol/l. As a measurement apparatus, an absolute PL quantum yield measuring system (C9920, manufactured by Hamamatsu Photonics K.K.) was used, and measurement was performed at an excitation wavelength of 300 nm.

As shown in Table 1, the fluorescence quantum yield of H-1 is higher than that of H-2. Accordingly, since the results obtained from the compound A-2-8 and the compound e-1, which have the respective mother skeletons, are considered similar to those as described above, it is believed that the fluorescence quantum yield of the compound A-2-8 is higher than that of the compound e-1.

According to the effect described above, when a derivative of the new condensed polycyclic compound (H-1) of the present invention is used as a light-emitting material for an organic light-emitting element, a light-emitting element having a high efficiency can be provided.

### 2. Comparison of Sublimation Temperature

Next, a sublimation temperature of the compound A-2-8, the condensed polycyclic compound of the present invention, and that of the compound e-1, the comparison compound, are compared with each other. When the sublimation temperature of a compound is high, since a high temperature is required for sublimation thereof by vacuum deposition or the like, the compound may be thermally decomposed in some cases. Hence, a lower sublimation temperature is advantageous for vacuum deposition. By comparing H-2 with H-1, which is the structural difference between the compound A-2-8 and the compound e-1, the difference between the two compounds is compared with each other. Since the structure of H-2 has a significantly high molecule planarity, the molecules thereof are very easily overlapped with each other. Hence, since these molecules are liable to form a molecular association, H-2 has a high crystal lattice energy. Naturally, a compound having a high crystal lattice energy has a high sublimation temperature. Hence, H-2 has a high sublimation temperature.

On the other hand, in H-1, since the triphenylene group is bridged by one carbon atom, two alkyl groups protruding in an upper direction and a lower direction with respect to the bridging carbon atom function to destroy the planarity, and hence H-1 has an effect of suppressing molecules from being overlapped with each other. As a result, H-1 has a crystal lattice energy lower than that of H-2. Since the crystal lattice energy is low, the sublimation temperature of H-1 is lower than that of H-2. The difference in the structure between the compound A-2-8 and the compound e-1 is only one point whether as a partial structure, H-1 is provided or H-2 is provided. Accordingly, it is considered that the result of comparison between H-1 and H-2 is strictly the same as the result of comparison between the compound A-2-8 and the compound e-1. When H-1 is compared with H-2, H-1 has a sublimation temperature lower than that of H-2.

Therefore, the compound A-2-8 has a sublimation temperature lower than that of the compound e-1. When vacuum deposition of the compound A-2-8 is performed, the deposition temperature thereof is lower than that of the compound e-1, and it is preferable since the compound is not likely to be thermally decomposed.

In addition, in Table 2, a Δ-5% temperature indicates a temperature at which the weight is decreased by 5% when the temperature is increased at a rate of 10° C./min. As a measurement apparatus, a TGDTA measurement apparatus (Thermo Plus TG8120, manufacture by Rigaku Co., Ltd.) was used. A smaller value indicates a lower sublimation temperature.

### 3. Comparison of Ionization Potential

The ionization potential of the condensed polycyclic compound of the present invention is compared with that of the comparative compound. When the ionization potential of a compound is low, a drive voltage can be preferably decreased when the above compound is used for an organic compound layer of an organic light-emitting element. Since the new condensed polycyclic compound of the present invention is a compound including the structure of H-1 in which the two carbons of triphenylene are bridged with one carbon having two alkyl groups, electrons are donated to the triphenylene ring. Therefore, H-1 has a low ionization potential as compared to that of the triphenylene (H-2). It is also believed that as in the case of H-1, the compound of the present invention, which is the compound in which the inside of triphenylene is bridged with a carbon having alkyl groups, has a low ionization potential as compared with that of the compound including H-2.

Furthermore, when H-1 of the new condensed polycyclic compound of the present invention is partially substituted with an alkyl group, the above effect is further significantly increased.

As shown in Table 2, the compound A-2-8, which is the compound including the structure of H-1, has an ionization potential lower than that of the compound e-1, which is the compound including the structure of H-2, by 0.22 eV.

In addition, measurement of the ionization potential shown in Table 2 was performed in such a way that a film having a thickness of 20 nm was deposited on a glass substrate by vacuum deposition and was measured using a photo-electron spectrometer in air (AC-3, manufactured by Riken Keiki Co., Ltd.).

TABLE 2

| | Δ-5% | IONIZATION |
|---|---|---|
| | TEMPERATURE | POTENTIAL |
| COMPOUND NO. | ° C. | eV |
| EXAMPLE COMPOUND A-2-8 | 411 | 6.16 |
| COMPARATIVE COMPOUND e-1 | 480 | 6.38 |

As shown in Example 12 and Comparative Example 2, the effect described above was obtained in which when the compound A-2-8 was used as a host material of a light-emitting layer of an organic light-emitting element, compared with the case of using the compound e-1, current was likely to flow, and a light emission of 4,000 cd/m² was observed at a lower voltage.

When a compound using the new condensed polycyclic compound (H-1) of the present invention is used as a host material of a light-emitting layer of an organic light-emitting element, effects of reducing an injection barrier from a hole transport layer and decreasing a drive voltage of the organic light-emitting element.

### 4. Description of Suppression of Molecular Association Formation

Since the new condensed polycyclic compound (H-1) of the present invention is not so much overlapped between molecules, as for the light-emitting properties of the compound, concentration quenching and excimer emission by a molecular association can be suppressed.

The new condensed polycyclic compound of the present invention is preferably used as a host material of a light-emitting layer of an organic light-emitting element. The reason for this is that holes are easily injected, and in addition, the concentration quenching and the excimer emission can be suppressed.

In this embodiment, the host material is a compound having a largest weight ratio among compounds of the light-emitting layer. In addition, a guest material has a weight ratio lower than that of the host material among the compounds of the light-emitting layer and is a compound responsible for primary light emission. Furthermore, an assistant material has a weight ratio lower than that of the host material among the compounds of the light-emitting layer and is a compound to assist light emission.

Particular examples of the condensed polycyclic compound of the present invention are shown below. However, the present invention is not limited thereto.

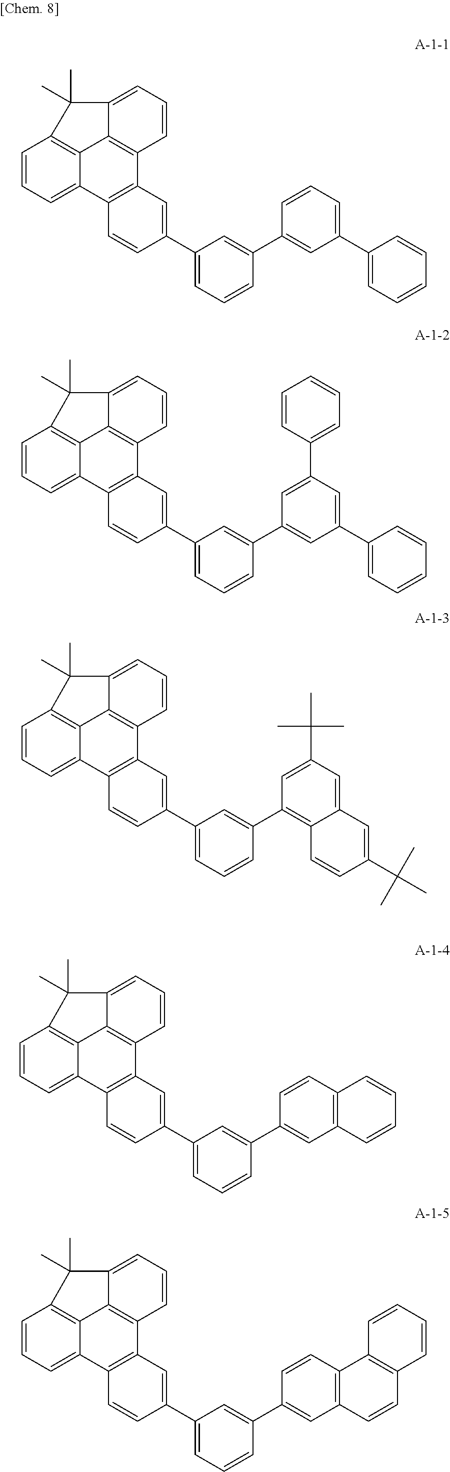

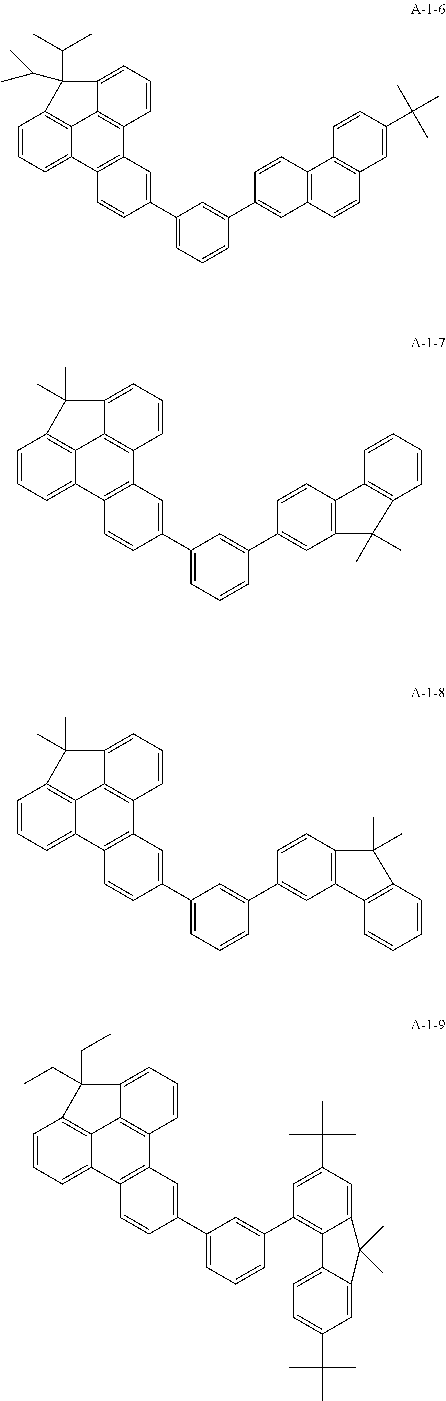

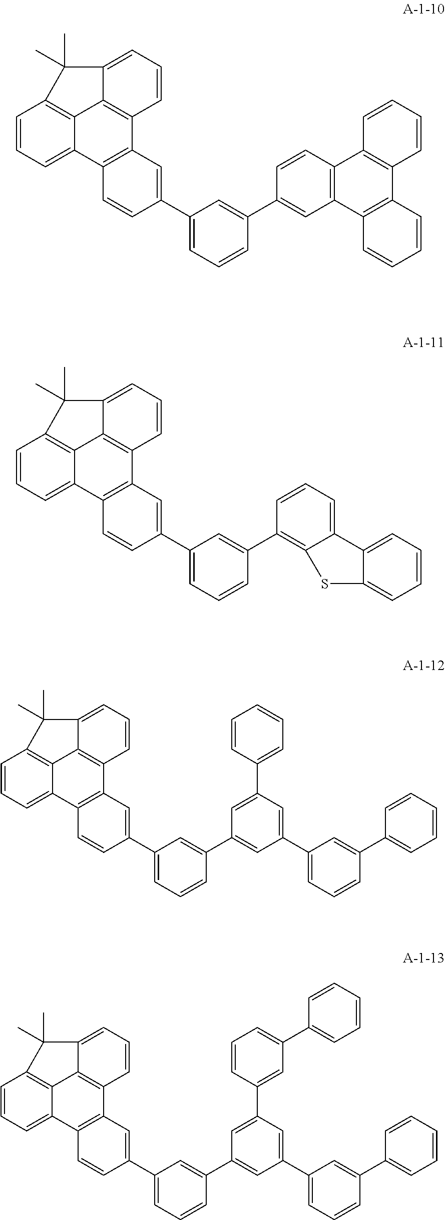

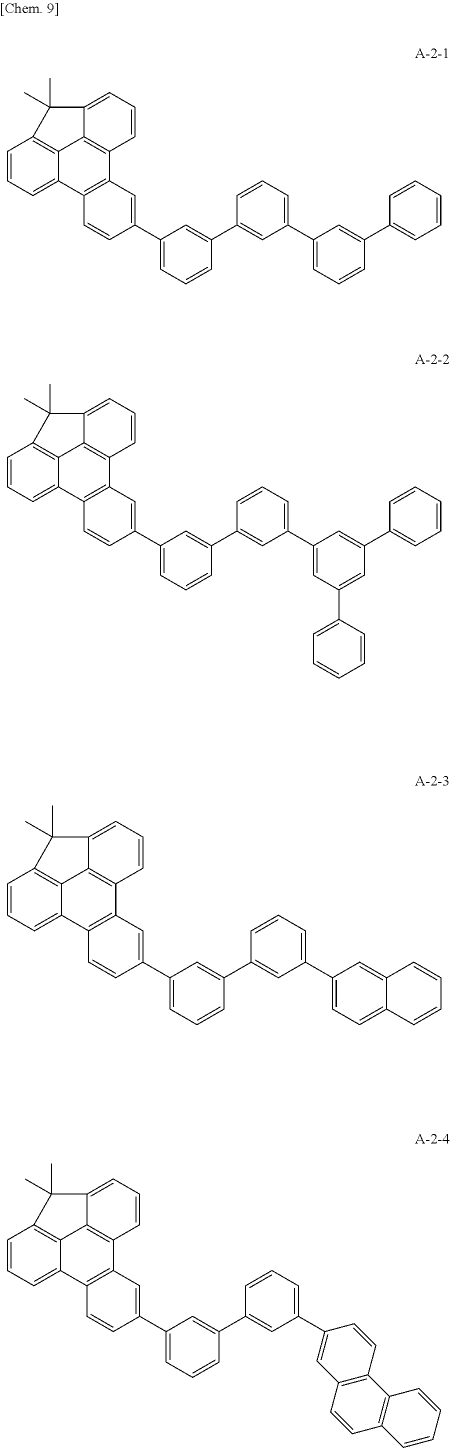

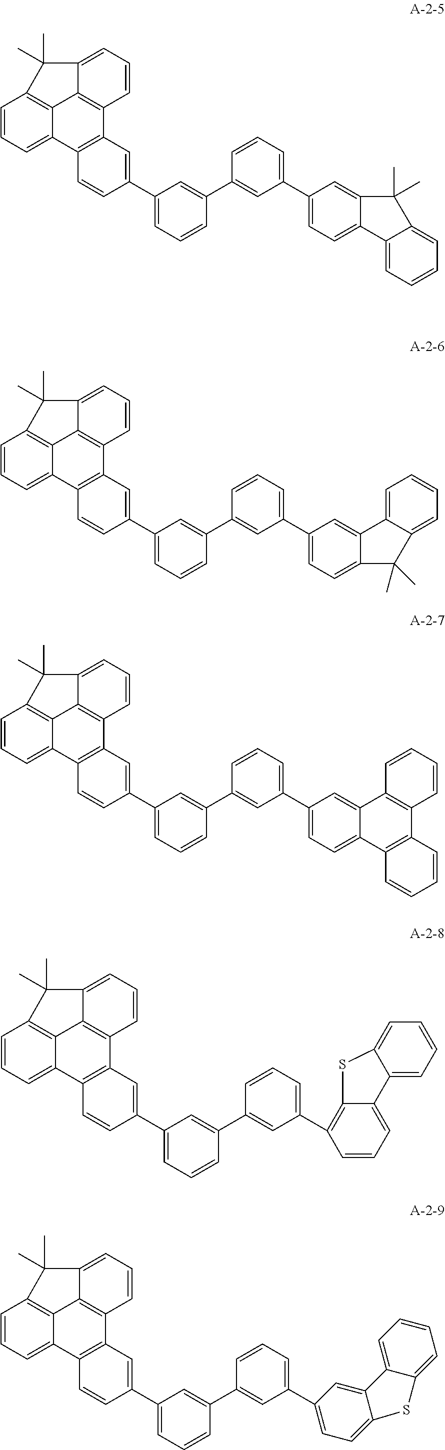

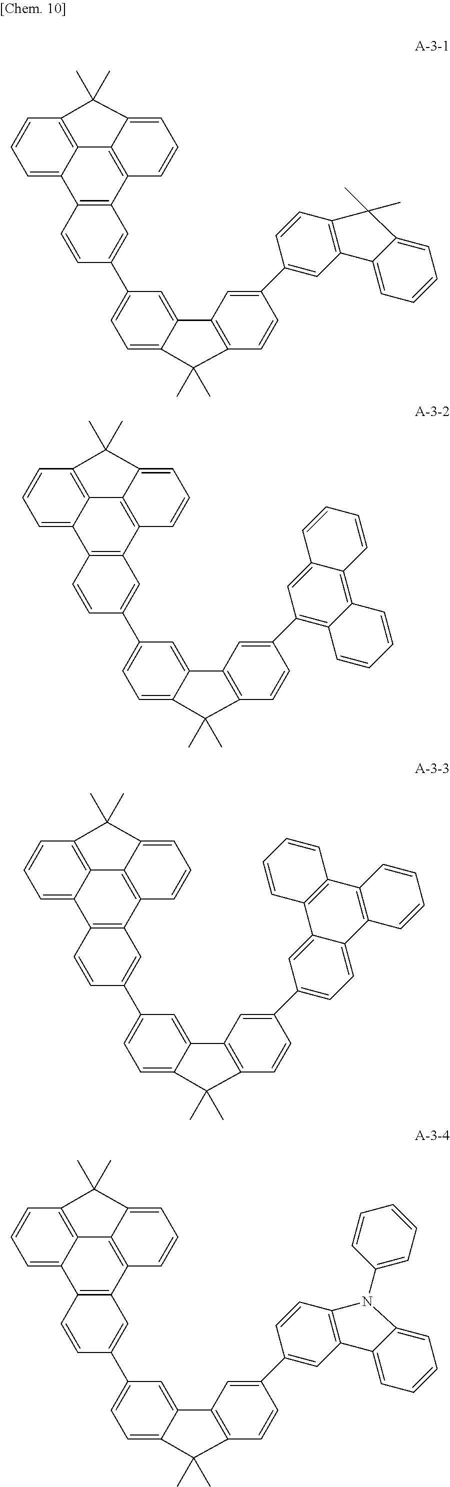

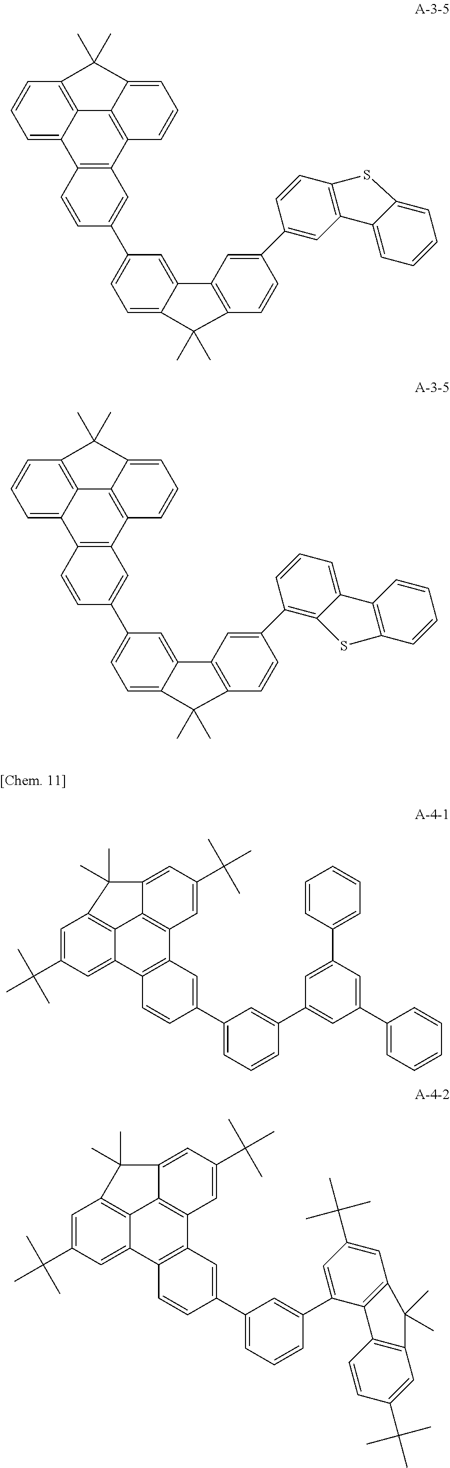

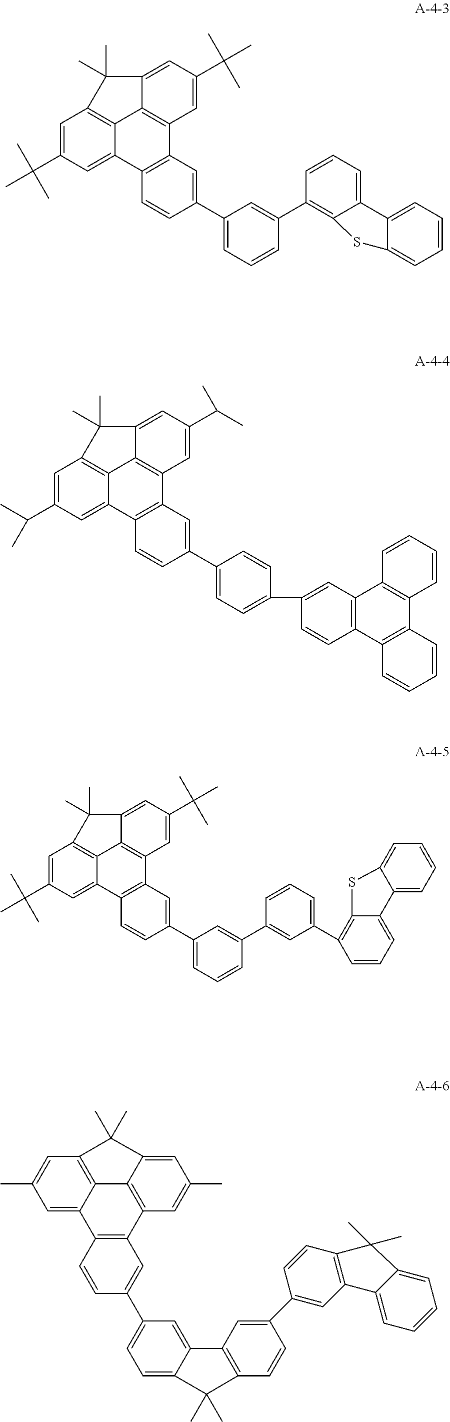

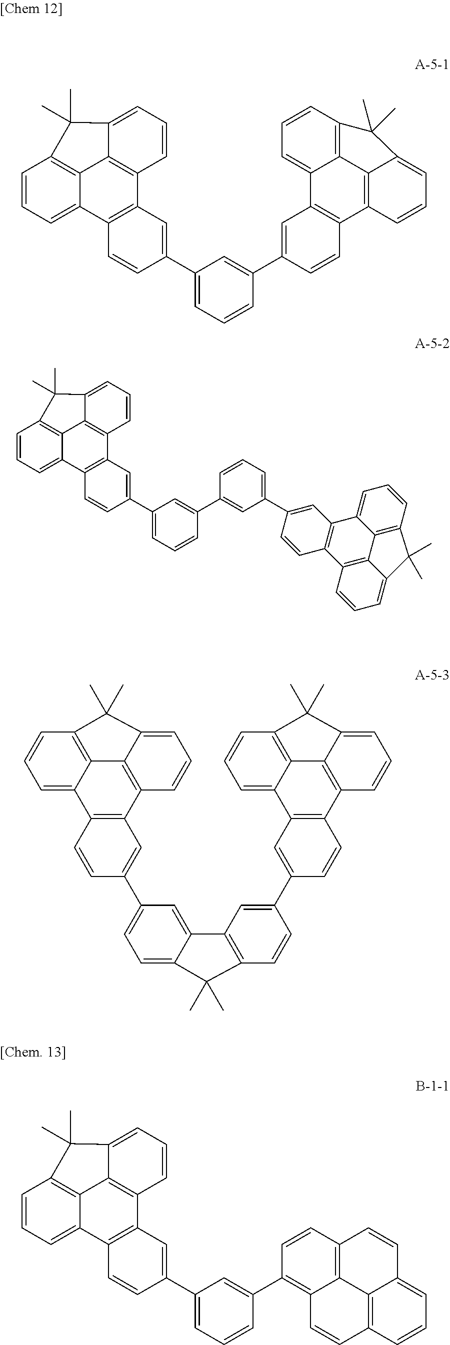

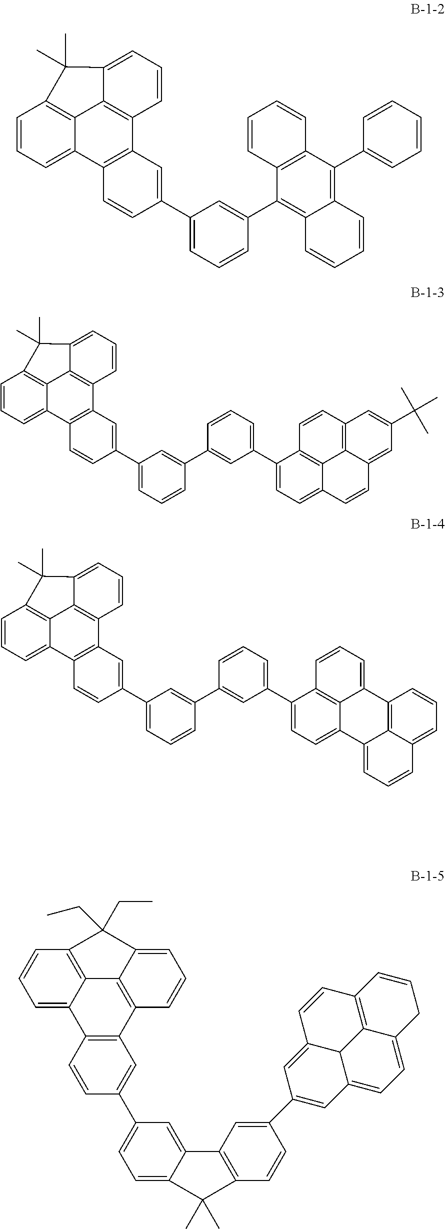

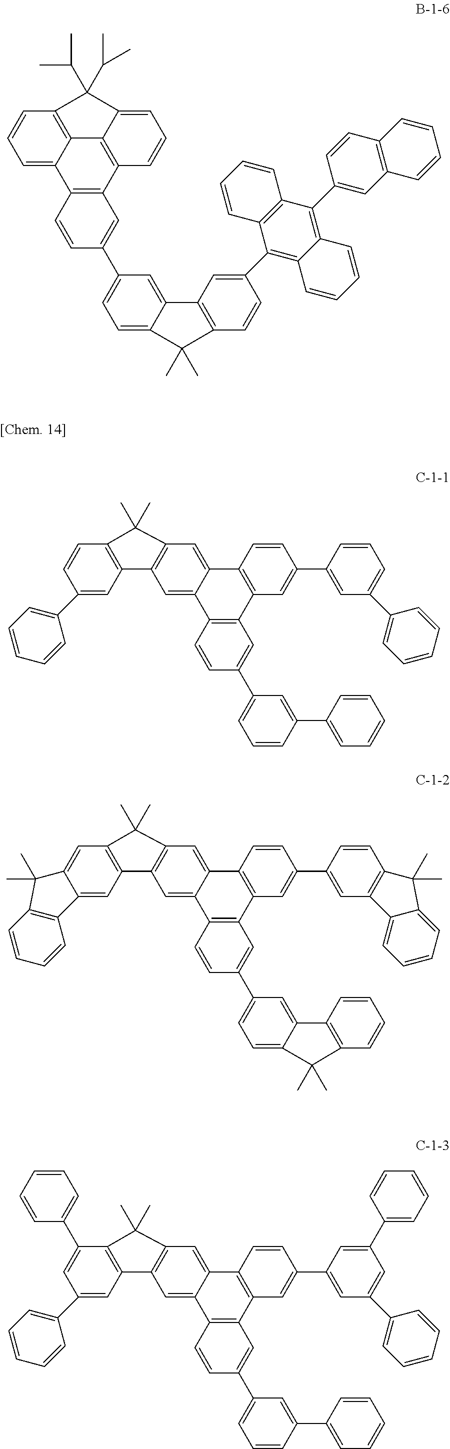

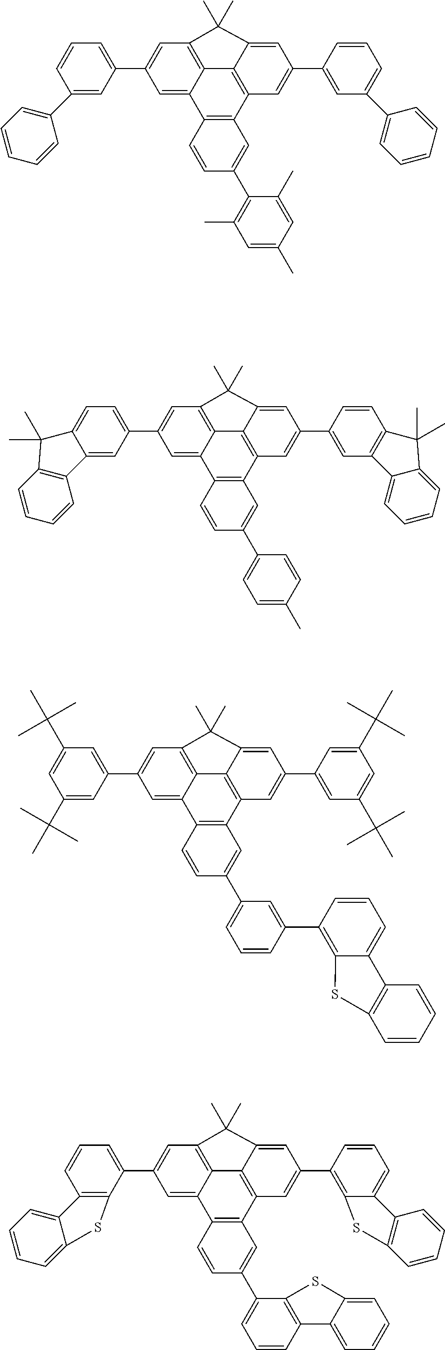

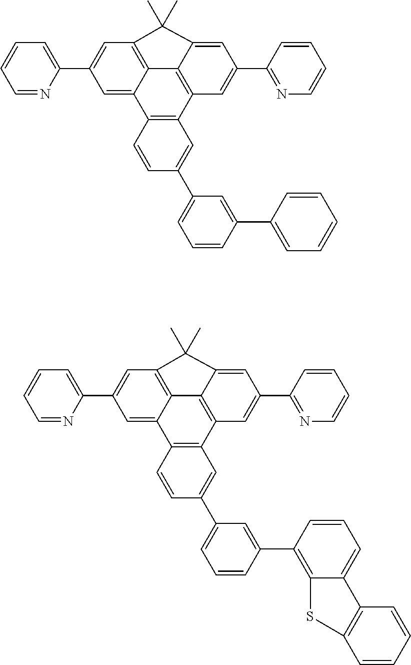 [SMILES: CC1(C)c2cc(-c3ccccn3)cc3c4ccc(-c5cccc(-c6ccccc6)c5)cc4c4cc(-c5ccccn5)cc1c4c23 ; CC1(C)c2cc(-c3ccccn3)cc3c4ccc(-c5cccc(-c6cccc7c6sc6ccccc67)c5)cc4c4cc(-c5ccccn5)cc1c4c23]

### (Properties of Example Compound)

### 1) A Group

Measured values of T1 in dilute solutions of representative example compounds of an A group are shown in Table 3. The measurement of T1 was carried out in such a way that a toluene solution (1×10⁻⁴ mol/l) was cooled to 77K, a phosphorescence emission spectrum was measured at an excitation wavelength of 350 nm, and the primary emission peak was regarded as T1. As a measurement apparatus, a spectrophotometer U-3010 manufactured by Hitachi Ltd. was used.

TABLE 3

| EXAMPLE COMPOUND NO. | Tl nm (MEASURED VALUE) |
|---|---|
| A-1-2 | 471 |
| A-1-8 | 472 |
| A-2-2 | 470 |
| A-2-4 | 472 |
| A-2-6 | 472 |
| A-2-8 | 472 |
| A-3-1 | 472 |

In the general formula [3], the compounds A-2-2, A-2-4, A-2-6, and A-2-8 each have hydrogen atoms as R1 and R2 and methyl groups as R3 and R4 and have different substituents as Ar. The T1 values of these compounds are all in a range of 470 to 472 nm and are almost equal to each other.

In the general formulas [2] to [4], the compounds A-1-8, A-2-6, and A-3-1 each have hydrogen atoms as R1 and R2, methyl groups as R3 and R4, and a dimethylfluorenyl group as Ar, and The T1 values of these compounds are all in a range of 470 to 472 nm and are almost equal to each other.

From the above two points, in the general formulas [2] to [4] of the present invention, when the T1 value of a simple substance of the Ar group is higher than that of a simple substance of the mother skeleton H-1, the T1 value is a value derived from the mother skeleton H-1. That is, the T1 value of the whole molecule is determined by the T1 value of the mother skeleton or that of the substituent, whichever is lower.

As the Ar group in the above case, for example, a dimethylfluorenyl group, a dibenzothiophenyl group, a phenanthrenyl group, a triphenylenyl group, and a naphthyl group may be mentioned. In this case, the T1 value of the whole molecule of each compound is in a range of approximately 470 to 472 nm.

Accordingly, the T1 values of the example compounds of the A group are in a range of approximately 470 to 472 nm, and the T1 energy is high. The T1 value of a phosphorescent light-emitting compound which emits green phosphorescence is in a range of 490 to 530 nm, and the compound of the present invention has a T1 energy higher than that thereof.

Hence, the condensed polycyclic compound of the present invention is preferably used as a host material of a light-emitting layer of an organic light-emitting element which emits green phosphorescence. The reason for this is that when energy is transferred to a guest material contained in the same light-emitting layer, the loss of energy is small.

Furthermore, the condensed polycyclic compound of the present invention can be used as a host material of a light-emitting layer of an organic light-emitting element which emits red phosphorescence or an electron transport material of an electron transport layer of an organic light-emitting element which emits green phosphorescence. In this case, the compound which emits green phosphorescence is a guest material of a light-emitting layer.

### 2) B Group

The example compounds shown in a B group have condensed polycyclic (such as pyrene, anthracene, and perylene) groups having a high fluorescence quantum yield as Ar of the general formulas [1] to [4]. These compounds have a high fluorescence quantum yield, and when being used as a host material of a light-emitting layer of an organic light-emitting element which emits fluorescence, the above compounds can provide a light-emitting element having a high efficiency.

### 3) C Group

The example compounds in a C group shows a compound group in which R1, R2, and R5 of the general formula [1] represent aryl groups. Since bulky aryl groups are provided so as to cover the mother skeleton H-1, an effect of suppressing the formation of a molecular association is significantly high, and the glass transition temperature is also high. In addition, since a biphenyl group and/or a fluorenyl group having a high fluorescence quantum yield is used, the fluorescence quantum yield is increased.

### (Description of Synthetic Route)

One example of a synthetic route of the condensed polycyclic compound of the present invention will be described. An intermediate a-4 which is the mother skeleton of the present invention can be synthesized between 4-bromofluorene intermediate a-1 and chloro, bromo, iodo benzene by the Suzuki-Miyaura coupling reaction and the Heck reaction. The intermediate a-4 can be formed as a chloro compound which is an effective raw material for synthesizing the compound represented by each of the general formulas [1] to [3]. The intermediate a-4 may be a halogen compound other than the chloro compound, a triflate compound, or a pinacol boron compound.

In addition, as the intermediate a-4, when an intermediate a-6 in which R1 and R2 each represent a hydrogen atom is used, a compound having two types of aryl groups, Ar1 and Ar2, can be synthesized from the intermediate a-6.

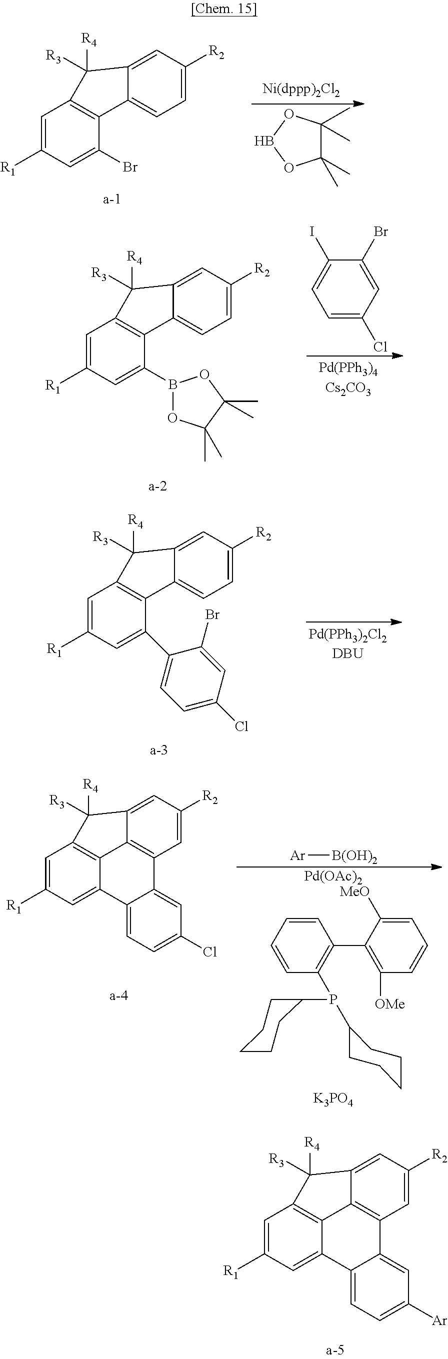

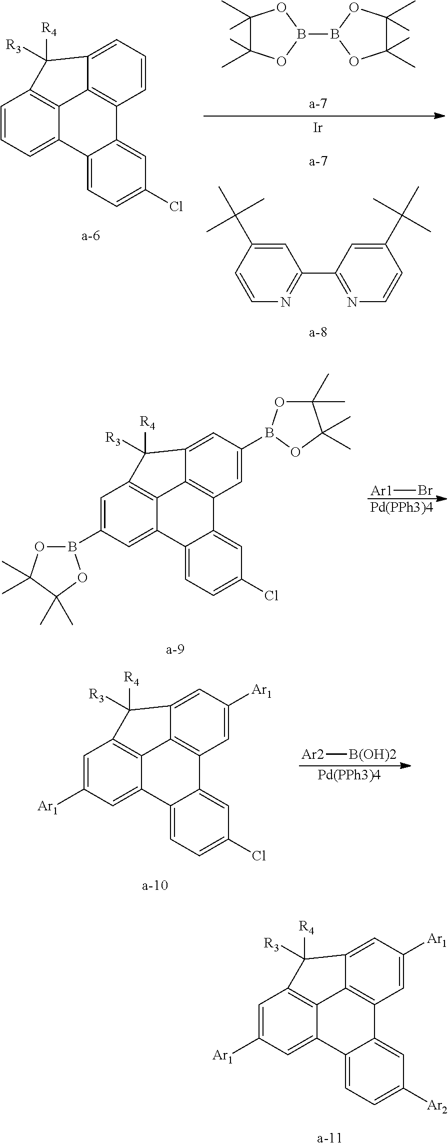

### (Description of Organic Light-Emitting Element)

Next, an organic light-emitting element according to this embodiment will be described.

The organic light-emitting element according to this embodiment has an anode and a cathode, which are one example of a pair of electrodes, and an organic compound layer arranged therebetween and is an element in which this organic compound layer contains at least one of the organic compounds represented by the general formulas [1] or [3].

As a layer structure of an organic light-emitting element formed using the organic compound of the present invention, the structure in which an anode, a light-emitting layer, and a cathode are sequentially provided on a substrate is mentioned. In addition, the structure in which an anode, a hole transport layer, an electron transport layer, and a cathode are sequentially provided is also mentioned. Furthermore, there are also mentioned the structure in which an anode, a hole transport layer, a light-emitting layer, an electron transport layer, and a cathode are sequentially provided; the structure in which an anode, a hole injection layer, a hole transport layer, a light-emitting layer, an electron transport layer, and a cathode are sequentially provided; and the structure in which an anode, a hole transport layer, a light-emitting layer, a hole/exciton blocking layer, an electron transport layer, and a cathode are sequentially provided. However, examples of these five multilayer types are each a very fundamental element structure, and the structure of an organic light-emitting element using the compound of the present invention is not limited to these described above.

The organic compounds represented by the general formulas [1] to [3] of the present invention can be used as a host material or a guest material of the light-emitting layer. In particular, when the above organic compound is used as a phosphorescence host material and is used in combination with a guest material which emits light from a green to a red region having a light emission peak in a region of 490 to 660 nm, the loss of triplet energy is small, and hence the efficiency of the light-emitting element is high.

When the condensed polycyclic compound of the present invention is used as a host material, the ratio thereof in a light-emitting layer is preferably in a range of 70 to 99.9 percent by weight and more preferably in a range of 90 to 99.5 percent by weight.

In addition, when the organic compound of the present invention is used as a guest material, the concentration of the guest material to a host material is preferably in a range of 0.1 to 30 percent by weight and more preferably in a range of 0.5 to 10 percent by weight.

The organic light-emitting element according to this embodiment may use known low and high molecular weight materials together with the organic compound of the present invention, if necessary.

Hereinafter, these compounds will be described by way of example.

As a hole injection material or a hole transport material, a material having a high hole mobility is preferable. As a low and a high molecular weight material having hole injection ability or hole transport ability, although a triarylamine derivative, a phenylenediamine derivative, a stilbene derivative, a phthalocyanine derivative, a porphyrin derivative, a poly(vinylcarbazole), a poly(thiophene), and other conductive polymers may be mentioned by way of example, the low and the high molecular weight materials are not limited thereto.

As a host material, for example, a triarylamine derivative, a phenylene derivative, a condensed-ring aromatic compound (such as a naphthalene derivative, a phenanthrene derivative, a fluorene derivative, or a chrysene derivative), an organometallic complex (such as an organic aluminum complex including tris(8-quinolate)aluminum, an organic beryllium complex, an organic iridium complex, or an organic platinum complex), and a polymer derivative, such as a poly(phenylenevinylene) derivative, a poly(fluorene) derivative, a poly(phenylene) derivative, a poly(thienylene vinylene) derivative, or a poly(acetylene) derivative, may be mentioned; however, of course, the host material is not limited thereto.

As a guest material, for example, the following platinum complex and Ir complex having phosphorescent light-emitting properties may be mentioned.

Example compounds K-1 to K-3 and K-5 are compounds which emit green light.

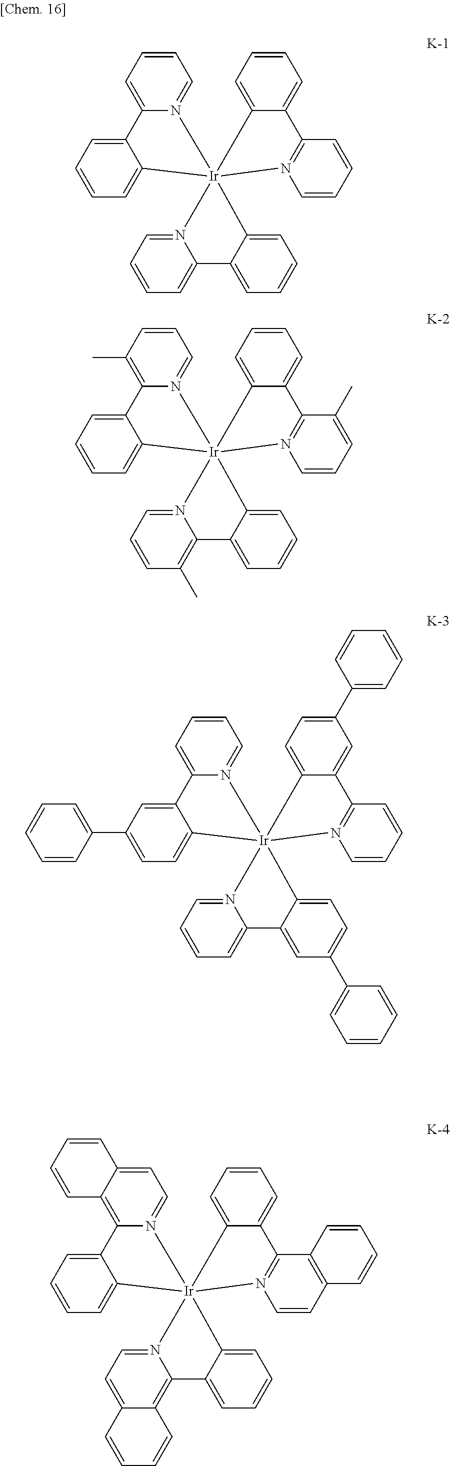

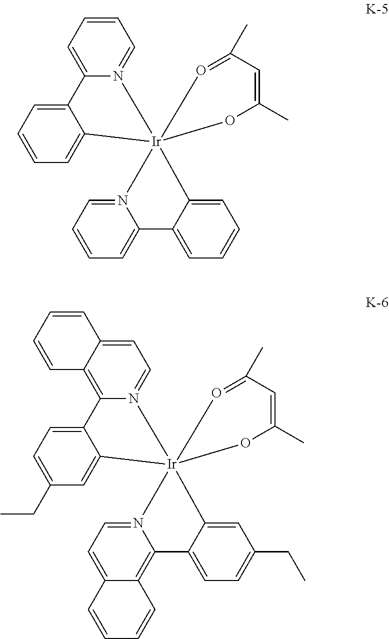

In addition, a dopant having fluorescent light-emitting properties may also be used, and for example, there may be mentioned a condensed-ring compound (such as a fluorene derivative, a naphthalene derivative, a pyrene derivative, a perylene derivative, a tetracene derivative, an anthracene derivative, or rubrene), a quinacridone derivative, a coumarin derivative, a stilbene derivative, an organic aluminum complex, such as a tris(8-quinolate) aluminum, an organic beryllium complex, and a polymer derivative, such as a poly(phenylenevinylene) derivative, a poly(fluorene) derivative, or a poly(phenylene) derivative.

As an electron injection material or an electron transport material, a material is selected in consideration, for example, of the balance with the hole mobility of a hole injection material or a hole transport material. As a material having electron injection ability or electron transport ability, for example, there may be mentioned an oxadiazole derivative, an oxazole derivative, a pyrazine derivative, a triazole derivative, a triazine derivative, a quinoline derivative, a quinoxaline derivative, a phenanthroline derivative, and an organic aluminum complex; however, of course, the above material is not limited thereto.

As an anode material, a material having a higher work function is more preferable. For example, there may be mentioned metal elements, such as gold, platinum, silver, copper, nickel, palladium, cobalt, selenium, vanadium, and tungsten, alloys thereof, and metal oxides, such as tin oxide, zinc oxide, indium oxide, indium tin oxide (ITO), and indium zinc oxide. In addition, conductive polymers, such as a polyaniline, a polypyrrole, and a polythiophene, may also be used. These electrode materials may be used alone, or at least two thereof may be used in combination. Furthermore, the anode may have a single layer structure or a multilayered structure.

On the other hand, as a cathode material, a material having a low work function is preferable. For example, there may be mentioned alkali metals such as lithium, alkaline earth metals, such as calcium, and metal elements, such as aluminum, titanium, manganese, silver, lead, and chromium. In addition, an alloy containing at least two of the above metal elements may also be used. For example, magnesium-silver, aluminum-lithium, aluminum-magnesium may also be used. Metal oxides, such as indium tin oxide (ITO), may also be used. These electrode materials may be used alone, or at least two thereof may be used in combination. Furthermore, the cathode may have a single layer structure or a multilayered structure.

In the organic light-emitting element according to this embodiment, a layer containing the organic compound according to this embodiment and layers of other organic compounds are formed by the following method. In general, the layers are each formed by a vacuum deposition method, an ionized evaporation method, a sputtering method, a plasma method, or a known coating method (such as a spin coating method, a dipping method, a casting method, an LB method, or an ink jet method) in which the compound is dissolved in a suitable solvent). When the layer is formed, for example, by a vacuum deposition method or a solution coating method, the crystallization is not likely to occur, and aging stability is excellent. In addition, when the layer is formed by a coating method, a film may also be formed in combination with a suitable binder resin.

As the binder resin, for example, a poly(vinylcarbazole) resin, a polycarbonate resin, a polyester resin, an ABS resin, an acrylic resin, a polyimide resin, a phenol resin, an epoxy resin, a silicone resin, and a urea resin may be mentioned; however, the binder resin is not limited thereto. In addition, these binder resins may be used alone as a homopolymer or a copolymer, or at least two of them may be used in combination by mixing. Furthermore, additives, such as known plasticizers, antioxidants, and ultraviolet absorbents may be used together, if necessary.

### (Application of Organic Light-Emitting Element)

The organic light-emitting element of the present invention can be used for a display device and a lighting device. Besides the above applications, the organic light-emitting element of the present invention may also be used, for example, for an exposure light source of an electrophotographic image forming device and a backlight of a liquid crystal display device.

The display device includes the organic light-emitting element according to this embodiment in a display portion. This display portion has a plurality of pixels. This pixel has the organic light-emitting element according to this embodiment and a TFT element as an example of a switching element for controlling luminescent brightness, and an anode or a cathode of this organic light-emitting element is connected to a drain electrode or a source electrode of the TFT element.

The display device including the organic light-emitting element according to this embodiment can be used as an image display device of a personal computer (PC) or the like.

The display device may be an image input device which has an input portion inputting image information from an area CCD, a linear CCD, a memory card, or the like and outputs the inputted image information on a display portion. In addition, a display portion of an imaging device or an inkjet printer may have both an image output function of displaying image information inputted from the outside and an input function of inputting processed information to an image as an operation panel. In addition, the display device may be used for a display portion of a multifunction printer, a head mount display, a digital camera, and the like.

The lighting device according to this embodiment has an organic light-emitting element and an inverter circuit connected thereto. The color of illumination light may be any one of white, day white, and monochromatic light and is not particularly limited.

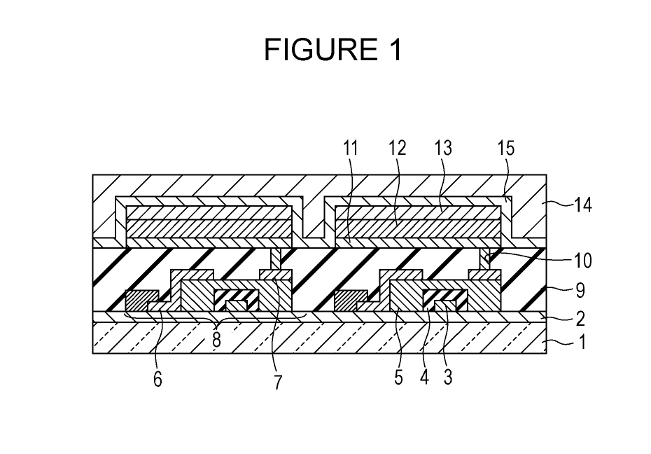

Next, a display device using the organic light-emitting element according to this embodiment will be described with reference to FIG. 1.

FIG. 1 is a schematic cross-sectional view of a display device showing the organic light-emitting element according to this embodiment and a TFT element which is one example of a switching element connected thereto. In this FIGURE, two sets are shown each containing the organic light-emitting element and the TFT element. The structure will be described in details.

This display device has a substrate 1 made of glass or the like and a moisture preventing film 2 provided thereon to protect the TFT element or an organic compound layer. In addition, reference numeral 3 indicates a metal gate electrode 3. Reference numeral 4 indicates a gate insulating film, and reference numeral 5 indicates a semiconductor layer.

A TFT element 8 has the semiconductor layer 5, a drain electrode 6, and a source electrode 7. An insulating film 9 is formed over the TFT element 8. An anode 11 of the organic light-emitting element and the source electrode 7 are connected to each other through a contact hole 10. The display device is not limited to this structure, and one of the anode and a cathode may be connected to one of the source electrode and the drain electrode of the TFT element.

An organic compound layer 12 including a plurality of organic compound layers is shown as one single layer in the FIGURE. On a cathode 13, a first protective layer 14 and a second protective layer 15 for suppressing degradation of the organic light-emitting element are provided.

In the display device according to this embodiment, the switching element is not particularly limited, and for example, a TFT element or an MIM element may be mentioned. As the TFT element, for example, a single-crystal-silicon type or an amorphous-Si type element may be used.

### EXAMPLES

Hereafter, the present invention will be described in detail with reference to examples. However, the present invention is not limited thereto.

### Example 1

### Synthesis of Example Compound A-2-8

Synthesis was carried out in accordance with the following synthetic scheme.

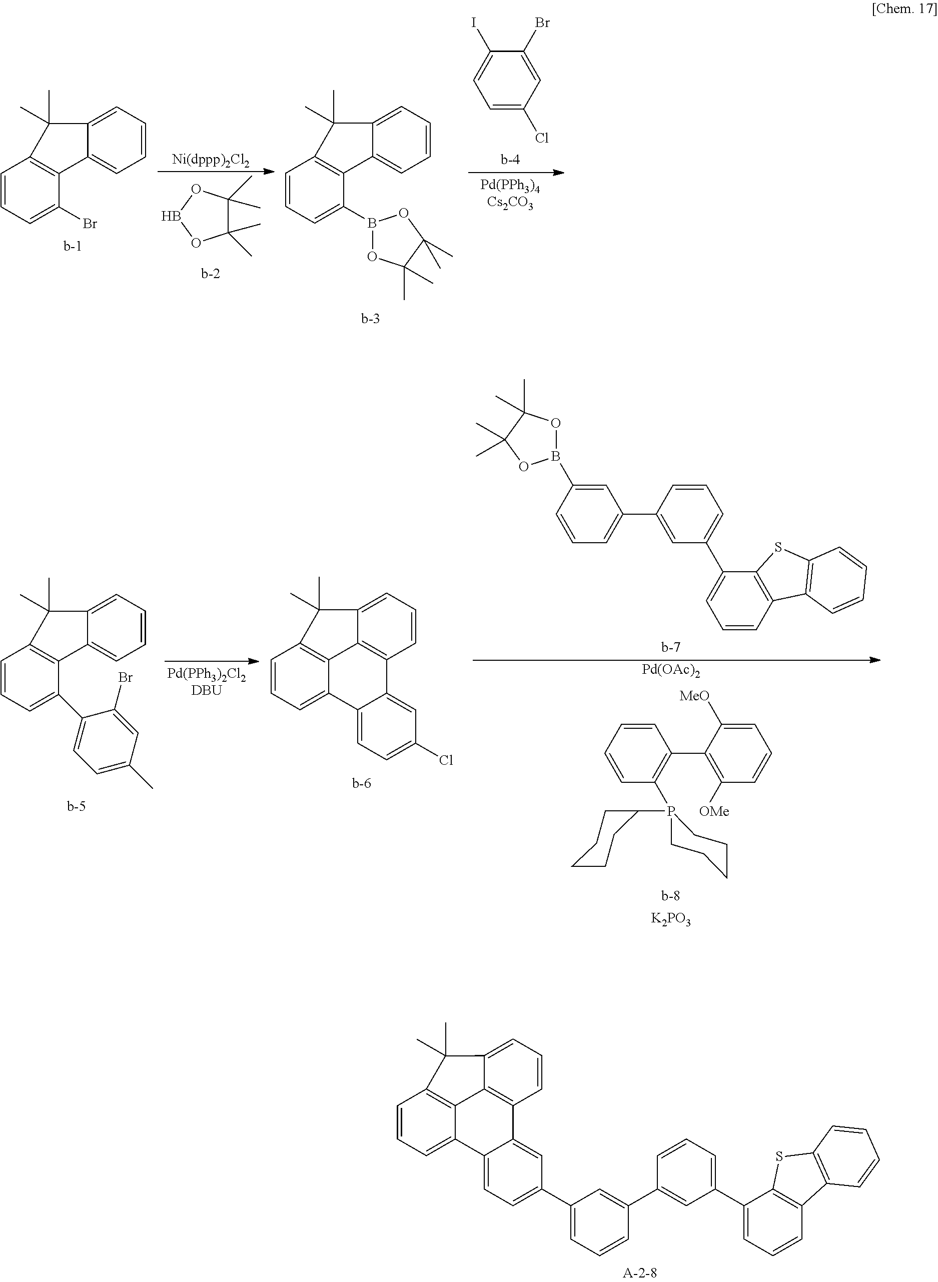

### Synthesis of Compound b-3

In a 300-ml three-neck flask, 7.0 g (26.0 mmol) of the compound b-1, 7.57 ml (52.0 mmol) of the compound b-2, 100 ml of toluene, and 20 ml of triethylamine were charged, and 1.4 g of [1,1′-bis(diphenylphosphino)propane]dichloro nickel was added at room temperature in a nitrogen atmosphere under stirring condition. The temperature was increased to 80° C., and stirring was performed for 8 hours. After the reaction, an organic layer was extracted with toluene, was then dried using anhydrous sodium sulfate, and was subsequently refined using a silica gel column (mixture of toluene and heptane: developing solvent), so that 7.45 g of the compound b-3 (white oil) (yield: 90.3%) was obtained.

### Synthesis of Compound b-5

In a 300-ml three-neck flask, 9.69 g (35.9 mmol) of the compound b-3, 17.0 g (53.6 mmol) of the compound b-4, 32.5 g (100 mmol) of cesium carbonate, 100 ml of toluene, 50 ml of ethanol, and 50 ml of water were charged in a nitrogen atmosphere, and 2.07 g of tetrakis(triphenylphosphine)palladium(0) was added at room temperature in a nitrogen atmosphere under stirring condition. The temperature was increased to 80° C., and stirring was performed for 12 hours. After the reaction, an organic layer was extracted with toluene, was then dried using anhydrous sodium sulfate, and was subsequently refined using a silica gel column (mixture of toluene and heptane: developing solvent), so that 9.56 g of the compound b-5 (white oil) (yield: 69.7%) was obtained.

### Synthesis of Compound b-6

In a 200-ml three-neck flask, 4.2 g (11.0 mmol) of the compound b-5, 6.69 g (44.0 mmol) of diazabicycloundecene (DBU), and 80 ml of DMF were charged in a nitrogen atmosphere, and 1.54 g of bis(triphenylphosphine)palladium dichloride was added at room temperature in a nitrogen atmosphere under stirring condition. The temperature was increased to 150° C., and stirring was performed for 24 hours. After the reaction, DMF was distilled off, and an organic layer was extracted with toluene, was then dried using anhydrous sodium sulfate, and was subsequently refined using a silica gel column (mixture of toluene and heptane: developing solvent), so that 1.73 g of the compound b-6 (transparent white) (yield: 52.0%) was obtained.

### Synthesis of Example Compound A-2-8

In a 100-ml three-neck flask, 0.50 g (1.66 mmol) of the compound b-6, 0.765 g (1.66 mmol) of the compound b-7, 0.185 g of potassium phosphate, 30 ml of toluene, and 0.2 ml of water were charged, and 20 mg of palladium acetate and 79 mg of the compound b-8 were added at room temperature in a nitrogen atmosphere under stirring condition. The temperature was increased to 80° C., and stirring was performed for 5 hours. After the reaction, an organic layer was extracted with toluene, was then dried using anhydrous sodium sulfate, and was subsequently refined using a silica gel column (mixture of toluene and heptane: developing solvent), so that 0.751 g of the example compound A-2-8 (white solid) (yield: 75%) was obtained.

By mass spectrometry, 603, which was M+ of the example compound A-2-8, was confirmed.

In addition, the structure of the example compound A-2-8 was confirmed by ¹H NMR measurement. ¹H NMR (CDCl₃, 400 MHz) σ(ppm): 8.91 (s, 1H), 8.72 (d, 1H), 8.39 (d, 1H), 8.33 (d, 1H), 8.22-8.13 (m, 3H), 8.01 (d, 1H), 7.86-7.59 (m, 14H), 7.50-7.49 (m, 2H), 1.70 (s, 6H)

T1 of the following compound in a toluene dilute solution was measured.

The measured value of T1 of the example compound A-2-8 was 470 nm. In addition, measurement of T1 was carried out in such a way that a toluene solution (1×10⁻⁴ mol/l) was cooled to 77K, a phosphorescence emission spectrum was measured at an excitation wavelength of 350 nm, and the primary light emission peak was used as T1. As a measurement apparatus, a spectrophotometer U-3010 manufactured by Hitachi Ltd. was used.

The ionization potential of the example compound A-2-8 obtained by measurement was 6.16 eV. In addition, measurement of the ionization potential was performed in such a way that a film having a thickness of 20 nm was deposited on a glass substrate by vacuum deposition and was measured using a photo-electron spectrometer in air (AC-3, manufactured by Riken Keiki Co., Ltd.).

### Example 2

### Synthesis of Example Compound A-1-2

The example compound A-1-2 was synthesized in a manner similar to that of Example 1 except that the compound b-7 was changed to the following compound c-1.

By mass spectrometry, 572, which was M+ of the example compound A-1-2, was confirmed. In addition, T1 of the example compound A-1-2 in a toluene dilute solution measured in a manner similar to that of Example 1 was 471 nm.

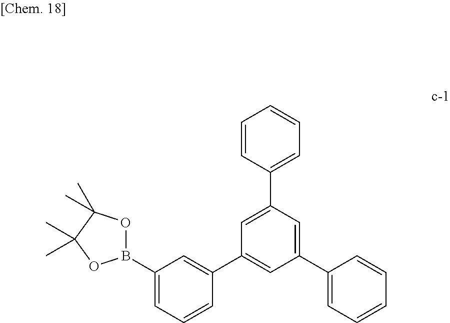 [SMILES: CC1(C)OB(c2cccc(-c3cc(-c4ccccc4)cc(-c4ccccc4)c3)c2)OC1(C)C]

### Example 3

### Synthesis of example compound A-1-8

The example compound A-1-8 was synthesized in a manner similar to that of Example 1 except that the compound b-7 was changed to the following compound c-2.

By mass spectrometry, 536, which was M+ of the example compound A-1-8, was confirmed. In addition, T1 of the example compound A-1-8 in a toluene dilute solution measured in a manner similar to that of Example 1 was 472 nm.

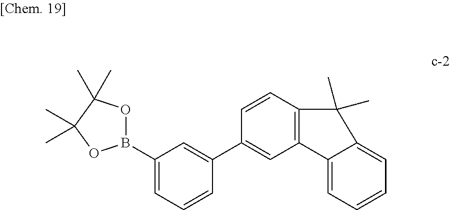 [SMILES: CC1(C)c2ccccc2-c2cc(-c3cccc(B4OC(C)(C)C(C)(C)O4)c3)ccc21]

### Example 4

### Synthesis of Example Compound A-2-2

The example compound A-2-2 was synthesized in a manner similar to that of Example 1 except that the compound b-7 was changed to the following compound c-3.

By mass spectrometry, 648, which was M+ of the example compound A-2-2, was confirmed. In addition, T1 of the example compound A-2-2 in a toluene dilute solution measured in a manner similar to that of Example 1 was 470 nm.

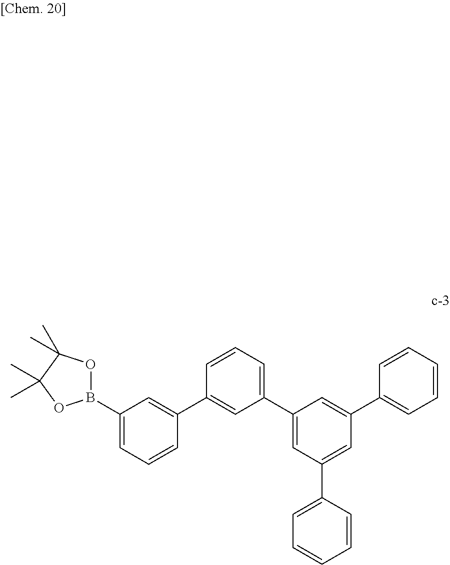 [SMILES: CC1(C)OB(c2cccc(-c3cccc(-c4cc(-c5ccccc5)cc(-c5ccccc5)c4)c3)c2)OC1(C)C]

### Example 5

### Synthesis of Example Compound A-2-4

The example compound A-2-4 was synthesized in a manner similar to that of Example 1 except that the compound b-7 was changed to the following compound c-4.

By mass spectrometry, 596, which was M+ of the example compound A-2-4, was confirmed. In addition, T1 of the example compound A-2-4 in a toluene dilute solution measured in a manner similar to that of Example 1 was 472 nm.

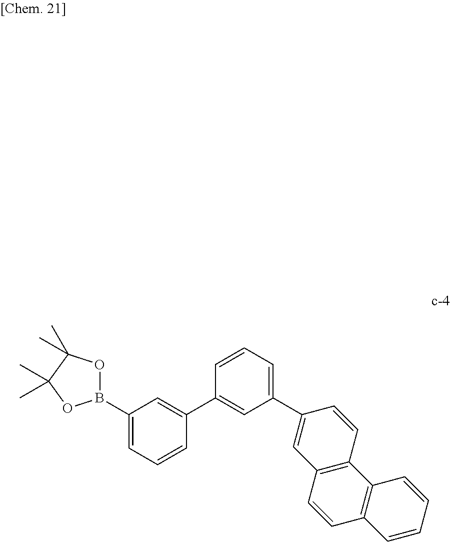 [SMILES: CC1(C)OB(c2cccc(-c3cccc(-c4ccc5c(ccc6ccccc65)c4)c3)c2)OC1(C)C]

### Example 6

### Synthesis of Example Compound A-2-6

The example compound A-2-6 was synthesized in a manner similar to that of Example 1 except that the compound b-7 was changed to the following compound c-5.

By mass spectrometry, 613, which was M+ of the example compound A-2-6, was confirmed. In addition, T1 of the example compound A-2-6 in a toluene dilute solution measured in a manner similar to that of Example 1 was 472 nm.

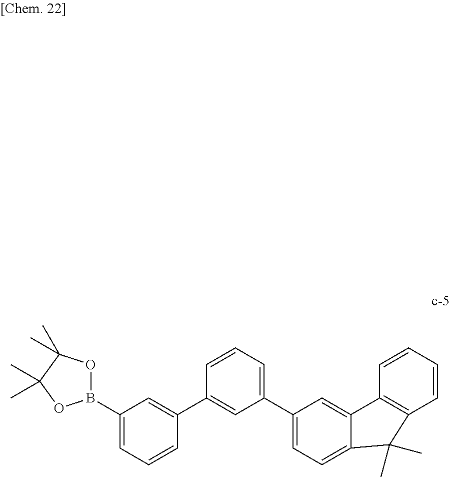 [SMILES: CC1(C)c2ccccc2-c2cc(-c3cccc(-c4cccc(B5OC(C)(C)C(C)(C)O5)c4)c3)ccc21]

### Example 7

### Synthesis of Example Compound A-3-1

The example compound A-3-1 was synthesized in a manner similar to that of Example 1 except that the compound b-7 was changed to the following compound c-6.

By mass spectrometry, 652, which was M+ of the example compound A-3-1, was confirmed. In addition, T1 of the example compound A-3-1 in a toluene dilute solution measured in a manner similar to that of Example 1 was 472 nm.

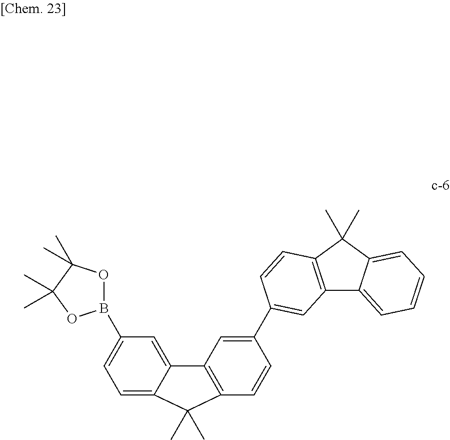 [SMILES: CC1(C)c2ccccc2-c2cc(-c3ccc4c(c3)-c3cc(B5OC(C)(C)C(C)(C)O5)ccc3C4(C)C)ccc21]

### Example 8

### Synthesis of Example Compound A-4-2

The example compound A-4-2 was synthesized in a manner similar to that of Example 1 except that the compound b-1 was changed to the following compound c-7, and the compound b-7 was changed to the following compound c-8.

By mass spectrometry, 760, which was M+ of the example compound A-4-2, was confirmed. In addition, T1 of the example compound A-4-2 in a toluene dilute solution measured in a manner similar to that of Example 1 was 473 nm.

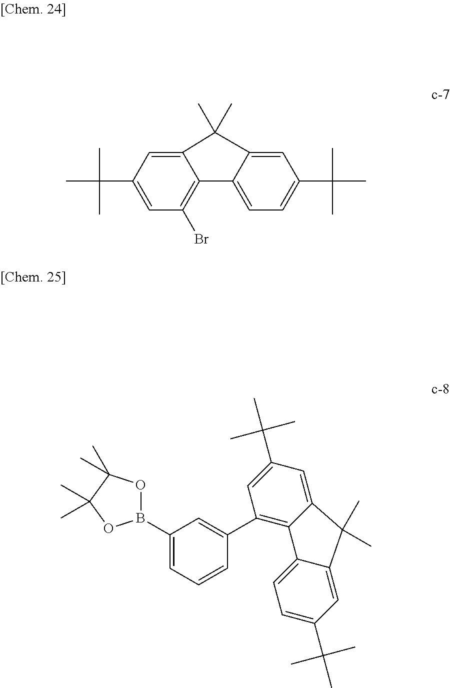

### Example 9

### Synthesis of Example Compound A-4-3

The example compound A-4-3 was synthesized in a manner similar to that of Example 1 except that the compound b-1 was changed to the following compound c-7, and the compound b-7 was changed to the following compound c-9.

By mass spectrometry, 639, which was M+ of the example compound A-4-3, was confirmed. In addition, T1 of the example compound A-4-3 in a toluene dilute solution measured in a manner similar to that of Example 1 was 473 nm.

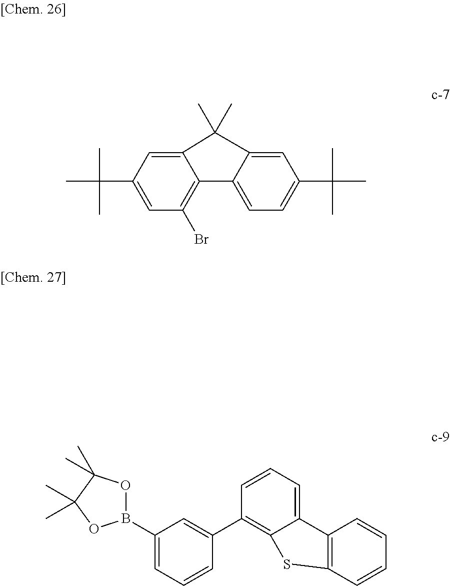

### Example 10

### Synthesis of Example Compound A-5-2

In a 100-ml three-neck flask, 0.50 g (1.66 mmol) of the compound b-6, 0.284 g (0.70 mmol) of the following compound c-10, 0.185 g of potassium phosphate, 30 ml of toluene, and 0.2 ml of water were charged, and 20 mg of palladium acetate and 79 mg of the compound b-8 were added at room temperature in a nitrogen atmosphere under stirring condition. The temperature was increased to 80° C., and stirring was performed for 5 hours. After the reaction, an organic layer was extracted with toluene, was then dried using anhydrous sodium sulfate, and was subsequently refined using a silica gel column (mixture of toluene and heptane: developing solvent), so that 0.332 g of the example compound A-5-2 (white solid) was obtained (yield: 69%).

By mass spectrometry, 687, which was M+ of the example compound A-5-2, was confirmed. In addition, T1 of the example compound A-5-2 in a toluene dilute solution measured in a manner similar to that of Example 1 was 470 nm.

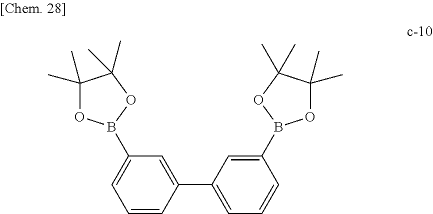

### Example 11

### Synthesis of Example Compound A-5-3

The example compound A-5-3 was synthesized in a manner similar to that of Example 10 except that the compound c-10 was changed to the following compound c-11.

By mass spectrometry, 727, which was M+ of the example compound A-5-3, was confirmed. In addition, T1 of the example compound A-5-3 in a toluene dilute solution measured in a manner similar to that of Example 1 was 471 nm.

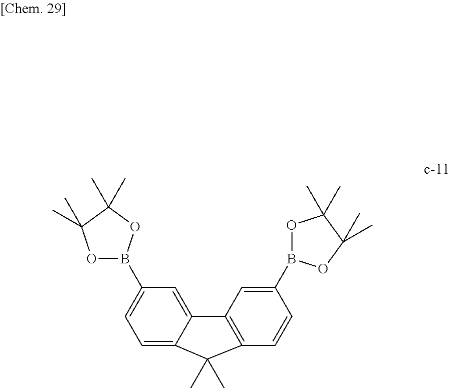

### Comparative Example 1

### Synthesis of Comparison Compound e-1

The comparative compound e-1 was synthesized in a manner similar to that of Example 1 except that the compound b-6 was changed to bromotriphenylene.

By mass spectrometry, 562, which was M+ of the comparative compound e-1, was confirmed.

The ionization potential of the comparative compound e-1 obtained by measurement was 6.38 eV. In addition, measurement of the ionization potential was performed in such a way that a film having a thickness of 20 nm was deposited on a glass substrate by vacuum deposition and was measured using a photo-electron spectrometer in air (AC-3, manufactured by Riken Keiki Co., Ltd.).

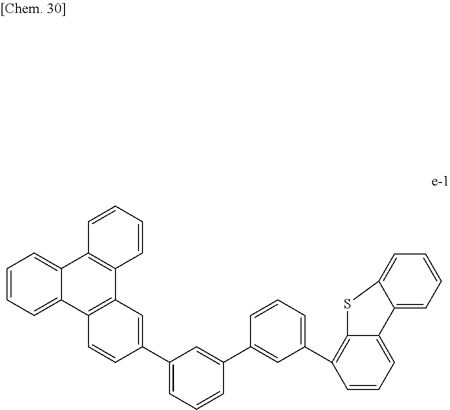 [SMILES: c1cc(-c2cccc(-c3cccc4c3sc3ccccc34)c2)cc(-c2ccc3c4ccccc4c4ccccc4c3c2)c1]

### Example 12

In this example, an organic light-emitting element having the structure in which an anode/a hole transport layer/a light-emitting layer/an electron transport layer/a cathode were sequentially provided on a substrate was formed by the following method.

An ITO film was formed as an anode by sputtering on a glass substrate to have a thickness of 120 nm, and this structure thus formed was used as a transparent conductive support substrate (ITO substrate). An organic compound layer and an electrode layer shown below were successively formed on this ITO substrate by vacuum deposition using resistance heating in a vacuum chamber at a pressure of 10⁻⁵ Pa. At this stage, the electrodes were formed to have a facing electrode area of 3 mm².

Hole transport layer (30 nm): d-1
Light-emitting layer (30 nm), host: A-2-8, and guest: d-2 (weight ratio 15%)
Hole exciton/blocking layer (10 nm): d-3
Electron transport layer (30 nm): d-4
Metal electrode layer 1 (1 nm): LiF
Metal electrode layer 2 (100 nm): aluminum

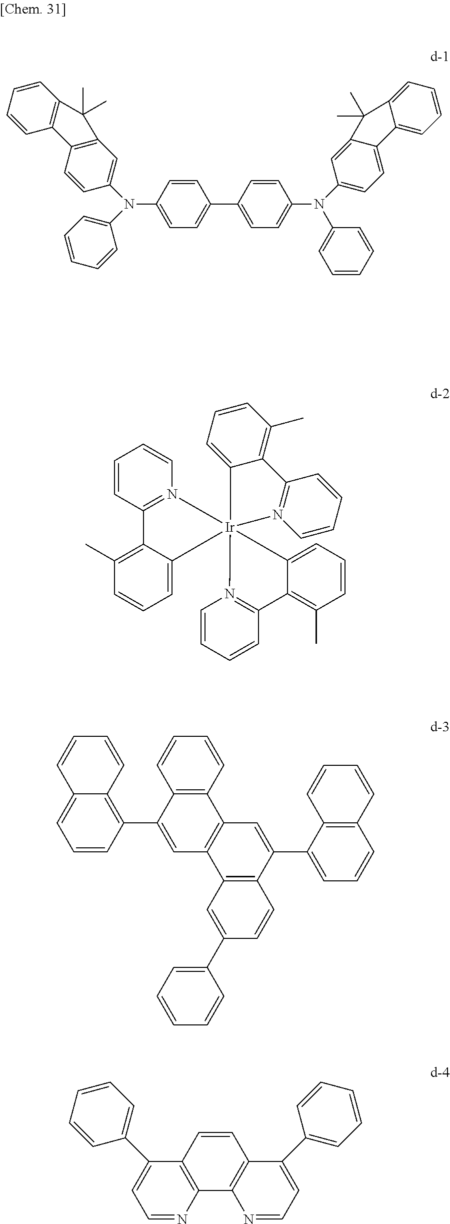

In the organic light-emitting element thus obtained, when a voltage of 4.0 V was applied between the ITO electrode functioning as a positive electrode and the Al electrode functioning as a negative electrode, the current density was 5.54 mA/cm². In addition, the voltage was 4.0 V and the light-emitting efficiency was 69 cd/A at a luminescent brightness of 4,000 cd/m², and the CIE chromaticity coordinates (0.35, 0.62) of green emission was observed.

### Comparative Example 2

An organic light-emitting element was formed in a manner similar to that of Example 12 except that the compound A-2-8 functioning as a host material of the light-emitting layer was changed to the comparison compound e-1.

In the organic light-emitting element thus obtained, when a voltage of 4.0 V was applied between the ITO electrode functioning as a positive electrode and the Al electrode functioning as a negative electrode, the current density was 0.52 mA/cm². In addition, the voltage was 4.8 V and the light-emitting efficiency was 69 cd/A at a luminescent brightness of 4,000 cd/m², and the CIE chromaticity coordinates (0.35, 0.62) of green emission was observed.

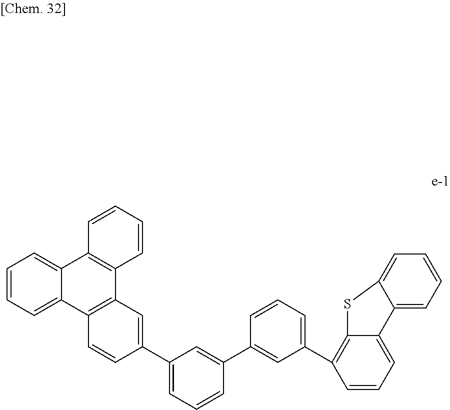 [SMILES: c1cc(-c2cccc(-c3cccc4c3sc3ccccc34)c2)cc(-c2ccc3c4ccccc4c4ccccc4c3c2)c1]

### Example 13

### Synthesis of Example Compound C-1-1

The example compound C-1-1 was synthesized in accordance with the following synthetic scheme.

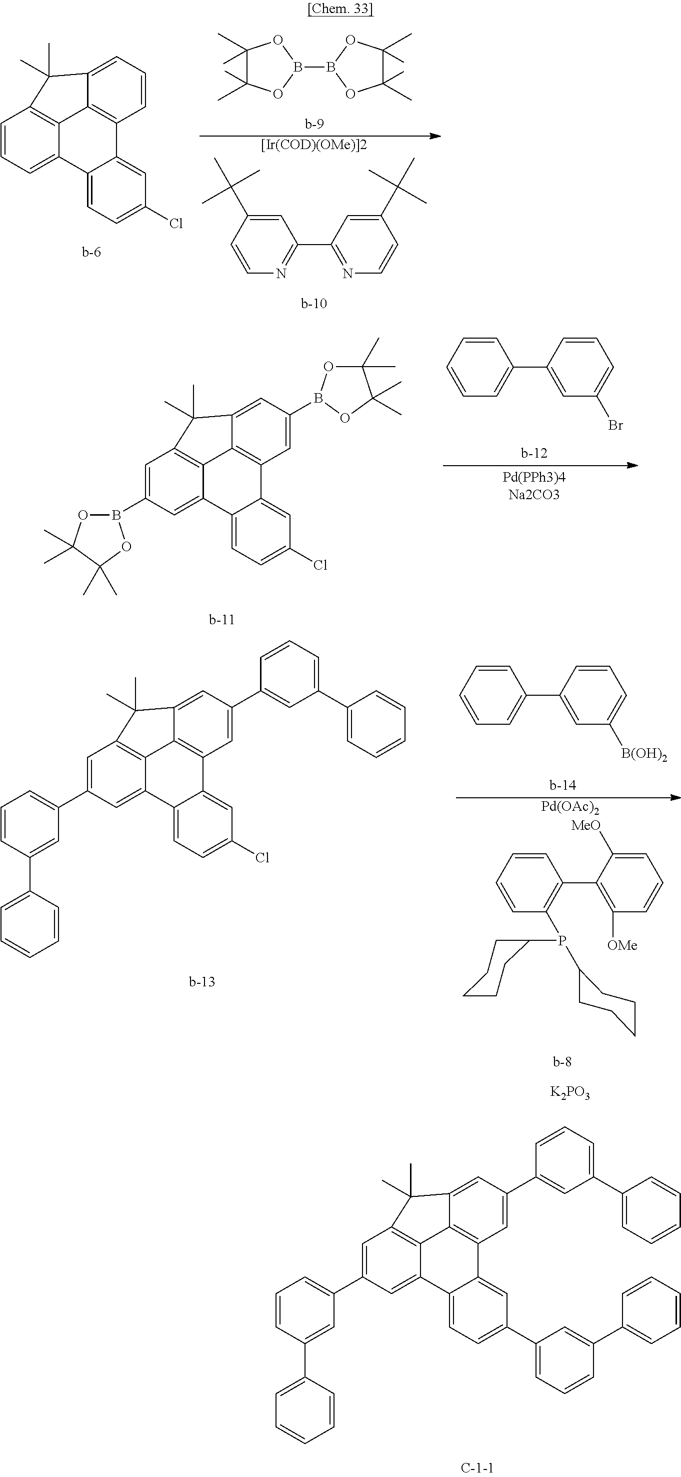

### Synthesis of Compound b-11

In a 50-ml three-neck flask, 0.906 g (3.0 mmol) of the compound b-6, 1.52 g (6.0 mmol) of the compound b-9, 0.161 g (0.60 mmol) of the compound b-10, and 20 ml of cyclohexane were charged, and 0.20 g of (1,5-cyclooctadiene)(methoxy)iridium(I) dimer was added at room temperature in a nitrogen atmosphere under stirring condition. The temperature was increased to 100° C., and stirring was performed for 8 hours. After the reaction, an organic layer was extracted with toluene, was then dried using anhydrous sodium sulfate, and was subsequently refined using a silica gel column (mixture of toluene and heptane: developing solvent), so that 1.08 g of the compound b-11 (white solid) (yield: 65%) was obtained.

### Synthesis of Compound b-13

In a 50-ml three-neck flask, 1.0 g (1.81 mmol) of the compound b-11, 0.501 g (2.16 mmol) of the compound b-12, 0.954 g (9 mmol) of sodium carbonate, 15 ml of toluene, 5 ml of ethanol, and 10 ml of water were charged in a nitrogen atmosphere, and 0.104 g of tetrakis(triphenylphosphine)palladium(0) was added at room temperature in a nitrogen atmosphere under stirring condition. The temperature was increased to 80° C., and stirring was performed for 5 hours. After the reaction, an organic layer was extracted with toluene, was then dried using anhydrous sodium sulfate, and was subsequently refined using a silica gel column (mixture of toluene and heptane: developing solvent), so that 0.905 g of the compound b-13 (white solid) (yield: 82.5%) was obtained.

### Synthesis of Example Compound C-1-1

In a 50-ml three-neck flask, 0.60 g (1.0 mmol) of the compound b-13, 0.165 g (1.20 mmol) of the compound b-14, 1.06 g of potassium phosphate, 30 ml of toluene, and 0.2 ml of water were charged, and 20 mg of palladium acetate and 79 mg of the compound b-8 were added at room temperature in a nitrogen atmosphere under stirring condition. The temperature was increased to 80° C., and stirring was performed for 5 hours. After the reaction, an organic layer was extracted with toluene, was then dried using anhydrous sodium sulfate, and was subsequently refined using a silica gel column (mixture of toluene and heptane: developing solvent), so that 0.55 g of the compound C-1-1 (white solid) (yield: 76%) was obtained.

By mass spectrometry, 724, which was M+ of the example compound C-1-1, was confirmed.

In addition, the structure of the example compound C-1-1 was confirmed by ¹H NMR measurement.

¹H NMR (CDCl₃, 400 MHz) σ(ppm): 8.96 (s, 1H), 8.81 (d, 1H), 8.58 (d, 2H), 8.03-8.02 (m, 4H), 7.89 (s, 2H), 7.83-7.79 (m, 3H), 7.75-7.70 (m, 6H), 7.65-7.59 (m, 6H), 7.53-7.46 (m, 6H), 7.42-7.37 (m, 3H), 1.81 (s, 6H)

T1 of the following compound in a dilute toluene solution was measured.

The measured value of T1 of the example compound C-1-1 was 482 nm. In addition, measurement of T1 was carried out in such a way that a toluene solution (1×10⁻⁴ mol/l) was cooled to 77K, a phosphorescence emission spectrum was measured at an excitation wavelength of 350 nm, and the primary light emission peak was used as T1. As a measurement apparatus, a spectrophotometer U-3010 manufactured by Hitachi Ltd. was used.

### Example 14)

### Synthesis of Example Compound C-1-2

The example compound C-1-2 was synthesized in a manner similar to that of Example 13 except that the compound b-12 was changed to the following compound c-12, and the compound b-14 was changed to the following compound c-13.

By mass spectrometry, 844, which was M+ of the example compound C-1-2, was confirmed. In addition, T1 of the example compound C-1-2 in a toluene dilute solution measured in a manner similar to that of Example 13 was 473 nm.

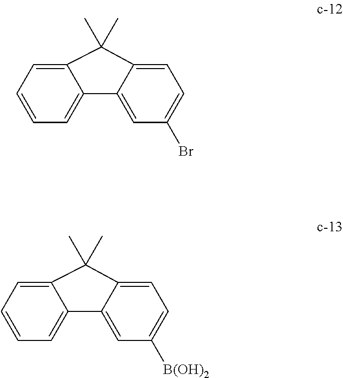 [SMILES: CC1(C)c2ccccc2-c2cc(Br)ccc21 ; CC1(C)c2ccccc2-c2cc(B(O)O)ccc21]

### Example 15

### Synthesis of Example Compound A-1-13

The example compound A-1-13 was synthesized in a manner similar to that of Example 1 except that the compound b-7 was changed to the following compound c-14.

By mass spectrometry, 724, which was M+ of the example compound A-1-13, was confirmed. In addition, T1 of the example compound A-1-13 in a toluene dilute solution measured in a manner similar to that of Example 13 was 472 nm.

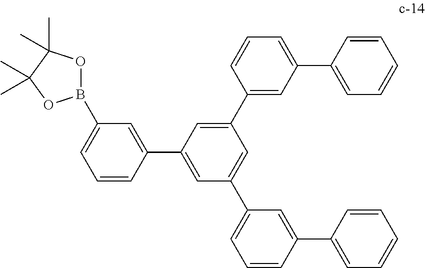 [SMILES: CC1(C)OB(c2cccc(-c3cc(-c4cccc(-c5ccccc5)c4)cc(-c4cccc(-c5ccccc5)c4)c3)c2)OC1(C)C]

### Example 16

An organic light-emitting element was formed in a manner similar to that of Example 12 except that the compound A-2-8 functioning as a host material of the light-emitting layer was changed to the example compound C-1-1.

In the organic light-emitting element thus obtained, when a voltage of 4.0 V was applied between the ITO electrode functioning as a positive electrode and the Al electrode functioning as a negative electrode, the current density was 0.48 mA/cm². In addition, the voltage was 4.6 V and the light-emitting efficiency was 63 cd/A at a luminescent brightness of 4,000 cd/m², and green emission was observed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-204248, filed Sep. 13, 2010, and No. 2011-112777, filed May 19, 2011, which are hereby incorporated by reference herein in their entirety.

### REFERENCE SIGNS LIST

8 TFT element
11 anode
12 organic compound layer
13 cathode

1. A condensed polycyclic compound represented by the following general formula [1], 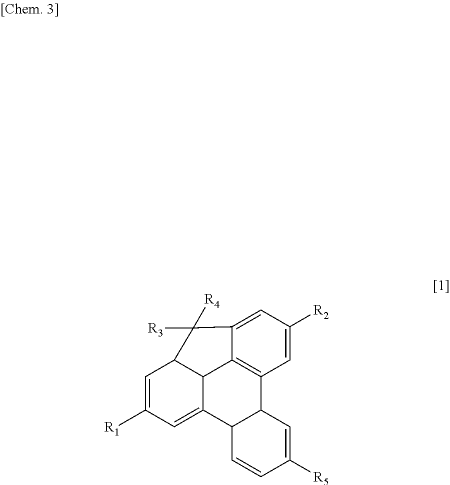
wherein in the general formula [1], R1, R2, and R5 are each independently selected from a hydrogen atom, an alkyl group having 1 to 4 carbon atoms, an aryl group, and a heterocyclic group,
R3 and R4 each represent an alkyl group having 1 to 4 carbon atoms, and
the aryl group and the heterocyclic group each may have at least one of an alkyl group, an aralkyl group, an aryl group, a heterocyclic group, an amino group, and an alkoxy group as a substituent.

2. The condensed polycyclic compound according to claim 1,
wherein in the general formula [1], R5 represents a phenyl group, a biphenyl group, or a fluorenyl group,
the phenyl group, the biphenyl group, and the fluorenyl group each may have at least one of an alkyl group having 1 to 4 carbon atoms, an aryl group, and a heterocyclic group as a substituent, and
the aryl group and the heterocyclic group each may have at least one of an alkyl group, an aralkyl group, an aryl group, a heterocyclic group, an amino group, and an alkoxy group as a substituent.

3. The condensed polycyclic compound according to claim 2,
wherein the condensed polycyclic compound is represented by one of the following general formulas [2] to [4] 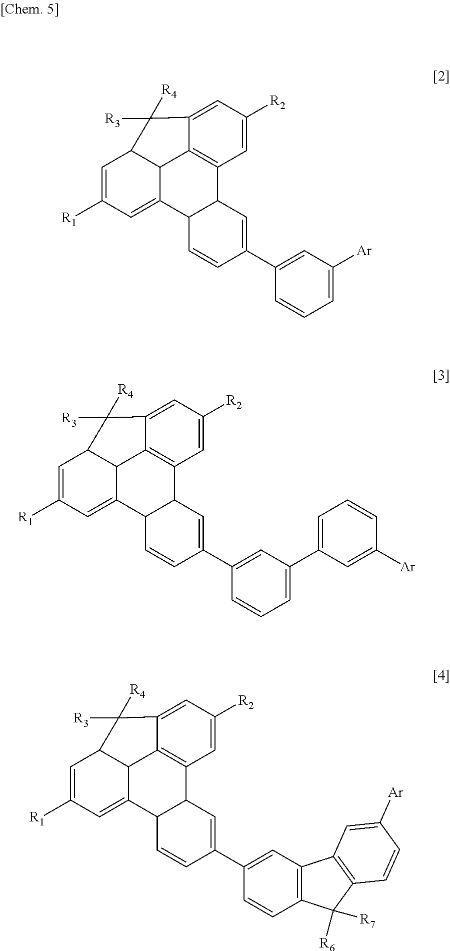
wherein in the general formulas [2] to [4], R1 and R2 are each independently selected from a hydrogen atom, an alkyl group having 1 to 4 carbon atoms, an aryl group, and a heterocyclic group,
R3 and R4 each represent an alkyl group having 1 to 4 carbon atoms,
the aryl group and the heterocyclic group each may have at least one of an alkyl group, an aralkyl group, an aryl group, a heterocyclic group, an amino group, and an alkoxy group as a substituent, and
Ar of each of the general formulas [2] to [4] represents an aryl group or a heterocyclic group, each of which may have at least one of an alkyl group, an aralkyl group, an aryl group, a heterocyclic group, an amino group, and an alkoxy group as a substituent.

4. An organic light-emitting element comprising:
a pair of electrodes; and
an organic compound layer arranged therebetween,
wherein the organic compound layer contains the condensed polycyclic compound according to claim 1.

5. The organic light-emitting element according to claim 4,
wherein the organic compound layer is a light-emitting layer which contains a host material and a guest material, and
the host material comprises the condensed polycyclic compound.

6. The organic light-emitting element according to claim 5,
wherein the guest material comprises a phosphorescent light-emitting compound.

7. A display device comprising:
a plurality of pixels,
wherein the pixels each have the organic light-emitting element according to claim 4 and a switching element connected thereto.

8. An image input device comprising:
a display portion displaying an image; and
an input portion inputting image information,
wherein the display portion has a plurality of pixels, and
the pixels each have the organic light-emitting element according to claim 4 and a switching element connected thereto.
